(19) United States
(12) Patent Application Publication
(10) Pub. No.: US 2026/0262462 A1
(43) Pub. Date: Sep. 3, 2026

(54) PRODUCTION METHOD FOR SEMICONDUCTOR CHIP WITH RESIN LAYER AND PRODUCTION METHOD FOR SUBSTRATE LAMINATE

(71) Applicant: MITSUI CHEMICALS, INC., Chuo-ku, Tokyo (JP)

(72) Inventors: Kahori TAMURA, Chuo-ku, Tokyo (JP); Satoshi INADA, Chuo-ku, Tokyo (JP); Yuzo NAKAMURA, Chuo-ku, Tokyo (JP); Yasuhisa KAYABA, Chuo-ku, Tokyo (JP)

(73) Assignee: MITSUI CHEMICALS, INC., Chuo-ku, Tokyo (JP)

(21) Appl. No.: 19/158,105

(22) PCT Filed: Feb. 21, 2024
(86) PCT No.: PCT/JP2024/006345

§ 371 Date: Aug. 20, 2025

(30) Foreign Application Priority Data
Feb. 21, 2023 (JP) 2023-025618

(51) Int. Cl. H10P 58/00; H10W 80/00

(52) U.S. Cl. CPC H10P 58/20; H10W 80/327

(57) ABSTRACT

Provided is a method of producing a resin layer-equipped semiconductor chip, the method including the steps of: preparing a laminated body that includes a semiconductor substrate and a resin layer stacked on the semiconductor substrate; attaching the laminated body to a dicing tape such that the resin layer is exposed; forming a protective layer on the resin layer of the laminated body; forming grooves penetrating through the protective layer and the resin layer by laser ablation; singulating the semiconductor substrate through the grooves; and removing a diced protective layer.

### TECHNICAL FIELD

The present disclosure relates to: a method of producing a resin layer-equipped semiconductor chip; and a method of producing a substrate laminated body.

### BACKGROUND ART

In association with the progress of reduction in size and weight and improvement in performance of electronic devices, there is a demand for higher integration of semiconductor chips and the like. However, the progress of miniaturization of circuits makes it more difficult to sufficiently meet the demand. Thus, in recent years, methods of achieving higher integration by stacking plural semiconductor substrates (wafers), semiconductor chips, and the like vertically (in the thickness direction) and thereby forming a multilayer three-dimensional structure have been proposed.

One example of a method of stacking and bonding semiconductor substrates (wafers), semiconductor chips, and the like (hereinafter, may be referred to as “semiconductor substrates and the like”) is a method of bonding the semiconductor substrates and the like to be stacked with solder being interposed between their electrodes. In association with miniaturization of circuits, however, this method has problems such as fusion of adjacent solder components, cracking due to alloying, and malfunction of a device caused by heat generated from solder.

Meanwhile, for example, direct bonding methods of directly bonding electrodes of semiconductor substrates and the like to be stacked without solder therebetween, and methods using an adhesive have been proposed (e.g., Patent Documents 1 to 3).

Further, as a method of dicing and singulating a semiconductor substrate into semiconductor chips, there has been proposed a dicing method such as plasma dicing, in which a patterned mask is formed on a semiconductor substrate, and parts of the semiconductor substrate on which the mask is not formed are singulated by plasma etching.

For example, Patent Document 4 discloses a method of producing an element chip, the method including: preparing a substrate that includes a first layer which is a semiconductor layer formed of silicon or the like, and a second layer obtained by forming an insulating film of SiO₂ or the like on the first layer; irradiating a dividing region of the substrate with laser light to form an opening through which the first layer is exposed in the second layer; depositing a protective film on an element region and the dividing region and subsequently allowing the protective film covering an end surface of the element region to remain by means of plasma; and then performing plasma dicing in which the first layer is etched with plasma through the opening and divided into element chips to obtain element chips in each of which an end surface of the second layer is covered with the protective film.
Patent Document 1: Japanese Patent Application Laid-Open (JP-A) No. H4-132258
Patent Document 2: JP-A No. 2010-226060
Patent Document 3: JP-A No. 2016-47895
Patent Document 4: JP-A No. 2017-163073

### SUMMARY OF THE INVENTION

### Technical Problem

In a case where an insulating layer such as a SiO₂ film is formed on a semiconductor substrate, grooves (openings) are formed on the insulating layer by laser ablation, and the semiconductor substrate is subsequently diced through the grooves and thereby singulated into semiconductor chips, the edges of the grooves (openings) formed by laser ablation have large irregularities, and these irregularities affect the dicing performed as a subsequent step, resulting in large irregularities on the side surfaces (cut surfaces) of the semiconductor chips. Such irregularities on the side surfaces of the semiconductor chips are likely to cause the generation of particles. When stacking and bonding the semiconductor chips, the presence of particles on a bonding surface leads to defective bonding.

One aspect of the disclosure was made in view of the above-described problems, and an object of one aspect of the disclosure is to provide: a method of producing a resin layer-equipped semiconductor chip in which, when grooves are formed in an insulating layer on a semiconductor substrate by laser ablation and the semiconductor substrate is subsequently diced through the grooves and thereby singulated into semiconductor chips, irregularities on the side surfaces, which are cut surfaces, of the semiconductor chips are reduced; and a method of producing a substrate laminated body.

### Solution to Problem

Concrete means for solving the above-described problems encompass the following.
<1> A method of producing a resin layer-equipped semiconductor chip, the method including:
   a laminated body preparation step of preparing a laminated body that includes a semiconductor substrate and a resin layer stacked on the semiconductor substrate;
   an attachment step of attaching the laminated body to a dicing tape such that the resin layer is exposed;
   a protective layer formation step of forming a protective layer on the resin layer of the laminated body;
   a groove formation step of forming grooves penetrating through the protective layer and the resin layer by laser ablation;
   a dicing step of singulating the semiconductor substrate through the grooves; and
   a protective layer removal step of removing the protective layer after the dicing step.
<2> The method of producing a resin layer-equipped semiconductor chip according to <1>, wherein the laminated body includes an electrode exposed from a part of the resin layer.
<3> The method of producing a resin layer-equipped semiconductor chip according to <1>, wherein the resin layer includes, on its surface, at least one functional group selected from the group consisting of a silanol group, an amino group, an epoxy group, a hydroxy group, and an unsaturated bond-containing functional group.
<4> The method of producing a resin layer-equipped semiconductor chip according to <1>, wherein the resin layer includes a siloxane bond and at least one bond selected from the group consisting of an ester bond, an ether bond, an amide bond, and an imide bond.
<5> The method of producing a resin layer-equipped semiconductor chip according to <1>, wherein the protective layer is a water-soluble resin layer formed of a water-soluble resin.
<6> The method of producing a resin layer-equipped semiconductor chip according to <1>, wherein, in the laminated body, an inorganic material layer is stacked on a side of the semiconductor substrate opposite to the side in which the resin layer is stacked.
<7> The method of producing a resin layer-equipped semiconductor chip according to <1>, wherein, in the dicing step, the protective layer and the resin layer on which the grooves are formed are used as a mask, and parts of the semiconductor substrate are plasma-etched through the grooves to singulate the semiconductor substrate.
<8> A method of producing a substrate laminated body, the method including:
   a stacking step of peeling off a resin layer-equipped semiconductor chip, which is produced by the method of producing a resin layer-equipped semiconductor chip according to any one of <1> to <7>, from the dicing tape, and stacking the resin layer-equipped semiconductor chip on other semiconductor substrate or other semiconductor chip such that the resin layer of the resin layer-equipped semiconductor chip is in contact with the other semiconductor substrate or the other semiconductor chip; and
   a heating step of heating and thereby bonding the thus stacked resin layer-equipped semiconductor chip and the other semiconductor substrate or the other semiconductor chip.
<9> The method of producing a substrate laminated body according to <8>, wherein
   the other semiconductor substrate or the other semiconductor chip includes an inorganic material layer, and
   in the stacking step, the stacking is performed such that the resin layer of the resin layer-equipped semiconductor chip is in contact with the inorganic material layer of the other semiconductor substrate or the other semiconductor chip.

### Advantageous Effects of Invention

According to one aspect of the disclosure, the following can be provided: a method of producing a resin layer-equipped semiconductor chip in which, when grooves are formed in an insulating layer on a semiconductor substrate by laser ablation and the semiconductor substrate is subsequently diced through the grooves and thereby singulated into semiconductor chips, irregularities on the side surfaces, which are cut surfaces, of the semiconductor chips are reduced; and a method of producing a substrate laminated body.

### BRIEF DESCRIPTION OF DRAWING

FIG. 1 is a schematic structural view that illustrates one example of a laminated body used in the method of producing a resin layer-equipped semiconductor chip according to the disclosure.

FIGS. 2(A) to 2(E) provide schematic views that illustrate the steps in one example of the method of producing a resin layer-equipped semiconductor chip according to the disclosure.

FIGS. 3(A) to 3(B) provide schematic views that illustrate the steps in one example of a method of producing a substrate laminated body by stacking a resin layer-equipped semiconductor chip, which is produced by the method of producing a resin layer-equipped semiconductor chip according to the disclosure, on other semiconductor chip.

FIG. 4 is an optical micrograph showing a portion of a side surface of the silicon substrate of the resin layer-equipped semiconductor chip produced in Example 1.

FIG. 5 is an optical micrograph showing a portion of a side surface of the silicon substrate of the SiO₂ layer-equipped semiconductor chip produced in Comparative Example 1.

FIG. 6 is an SEM image obtained by observing an end portion of the silicon substrate of the resin layer-equipped semiconductor chip produced in Example 1 from diagonally above.

FIG. 7 is an SEM image obtained by observing an end portion of the silicon substrate of the SiO₂ layer-equipped semiconductor chip produced in Comparative Example 1 from diagonally above.

FIG. 8 is a schematic structural view illustrating one example of a substrate laminated body produced by the method of producing a substrate laminated body according to the disclosure.

### DESCRIPTION OF EMBODIMENTS

In the disclosure, those numerical ranges that are expressed with “to” each denote a range that includes the numerical values stated before and after “to” as the lower limit value and the upper limit value, respectively.

In a set of numerical ranges that are stated in a stepwise manner in the disclosure, the upper limit value of one numerical range may be replaced with the upper limit value of other numerical range, and the lower limit value of one numerical range may be replaced with the lower limit value of other numerical range. Further, in a numerical range stated in the disclosure, the upper limit value or the lower limit value of the numerical range may be replaced with a relevant value indicated in any of Examples.

### [Method of Producing Resin Layer-Equipped Semiconductor Chip]

The method of producing a resin layer-equipped semiconductor chip according to the disclosure includes:
a laminated body preparation step of preparing a laminated body that includes a semiconductor substrate and a resin layer stacked on the semiconductor substrate;
an attachment step of attaching the laminated body to a dicing tape such that the resin layer is exposed;
a protective layer formation step of forming a protective layer on the resin layer of the laminated body;
a groove formation step of forming grooves penetrating through the protective layer and the resin layer by laser ablation;
a dicing step of singulating the semiconductor substrate through the grooves; and
a protective layer removal step of removing the protective layer after the dicing step.

In the method of producing a resin layer-equipped semiconductor chip according to the disclosure, a laminated body in which a resin layer is arranged on a semiconductor substrate is prepared, and a protective layer is further arranged on the resin layer, after which grooves are formed by laser ablation, and exposed parts (groove parts) of the semiconductor substrate are then diced and singulated (made into chips). As a result, as compared to a case of using a laminated body in which an inorganic layer such as a SiO₂ film is arranged on a semiconductor substrate, irregularities on the side surfaces, i.e., cut surfaces obtained by dicing, of the resulting semiconductor chips are reduced, so that the generation of particles caused by the irregularities on the side surfaces of the semiconductor chips can be inhibited. Therefore, for example, when peeling off a resin layer-equipped semiconductor chip from a dicing tape using a handling device and stacking the semiconductor chip on other semiconductor substrate or the like, the inclusion of particles between the semiconductor chip and the other semiconductor substrate or the like can be inhibited.

The reason why the method of the disclosure reduces irregularities on a side surface of a semiconductor layer of the resulting resin layer-equipped semiconductor chip is not clear; however, it is presumed as follows.

When a SiO₂ layer and a protective layer are arranged on a semiconductor substrate and grooves are formed on the SiO₂ layer and the protective layer by laser ablation or the like to pattern a mask, laser light is scattered by the SiO₂ layer, and vertical streaks (vertical stripes) are formed (in the thickness direction of the protective layer) on the inner wall surfaces of the grooves of the protective layer. It is presumed that when the semiconductor substrate is diced through a mask having such vertical streaks, the vertical streaks formed on the side surface of the mask (protective layer) are transferred to the cut surface of the semiconductor substrate.

On the other hand, when a resin layer and a protective layer are arranged on a semiconductor substrate and grooves are formed on the resin layer and the protective layer by laser ablation or the like to pattern a mask, scattering of laser light by the resin layer is inhibited, so that the formation of vertical streaks on the inner wall surfaces of the grooves of the protective layer is inhibited. Therefore, it is presumed that, at the time of dicing, the formation of vertical streaks on the resulting cut surface of the semiconductor substrate is inhibited. It is noted here, however, that the disclosure is not limited to the above-described presumption.

Hereinafter, examples of the method of producing a resin layer-equipped semiconductor chip according to the disclosure and the method of producing a substrate laminated body according to the disclosure will be described with reference to the attached drawings. It is noted here that the disclosure is not limited to the configurations illustrated in the drawings. The configurations such as the size and the shape of each member illustrated in the drawings are conceptual, and the relative relationships between the members are not limited thereto. Further, those members having substantially the same function are assigned with the same symbol in the respective drawings, and the symbols and description of redundant members may be omitted.

### <Method of Producing Resin Layer-Equipped Semiconductor Chip>

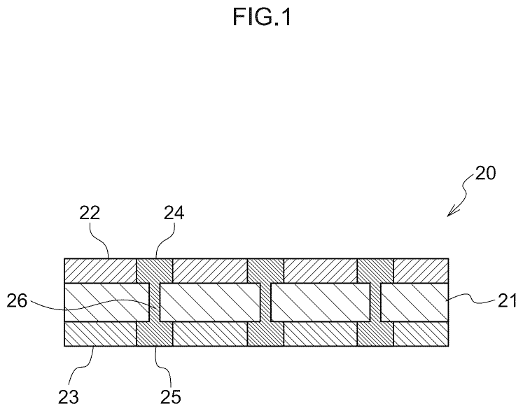

FIG. 1 schematically illustrates one example of the configuration of a laminated body 20 used in the method of producing a resin layer-equipped semiconductor chip according to the disclosure. In the laminated body 20 illustrated in FIG. 1, an inorganic material layer 22 composed of an inorganic material is arranged on one surface of a silicon substrate 21 which is a semiconductor substrate, and a resin layer 23 composed of a resin is arranged on the other surface. In addition, surface electrodes 24, which are each surrounded by the inorganic material layer 22 and exposed, are arranged on the one surface of the laminated body, and back surface electrodes 25, which are each surrounded by the resin layer 23 and exposed, are arranged on the other surface. Further, through electrodes 26, which penetrate through the silicon substrate 21 in the thickness direction and electrically connect the surface electrodes 24 and the back surface electrodes 25, are arranged.

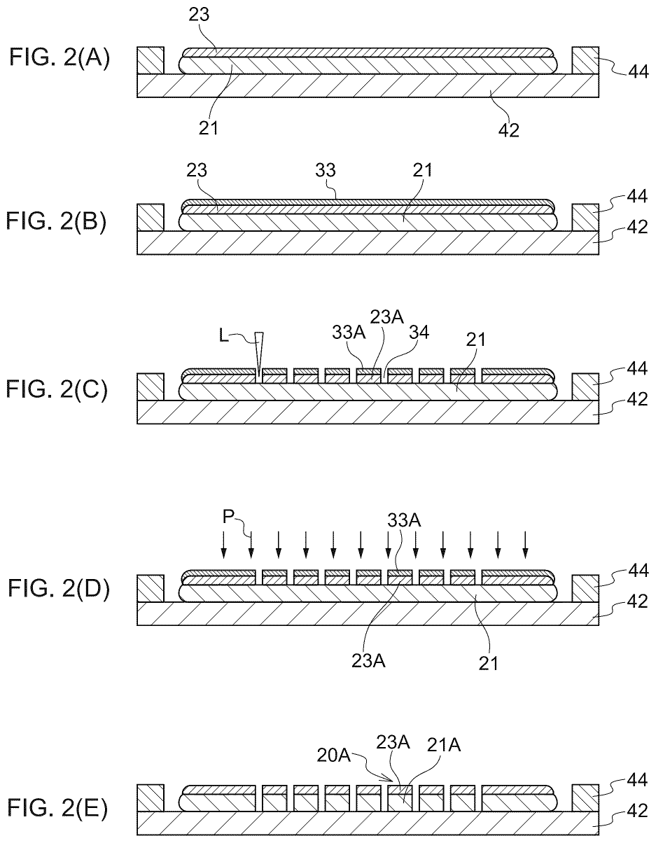

FIG. 2 schematically illustrates one example of the method of producing a resin layer-equipped semiconductor chip according to the disclosure. It is noted here that the electrodes 24, 25, and 26 as well as the inorganic material layer 22 illustrated in FIG. 1 are omitted in FIG. 2.
(A) The surface of the laminated body 20 on the side opposite to the resin layer 23 is attached to a dicing tape 42 (FIG. 2(A)).
(B) A protective layer 33 is formed on the resin layer 23 (FIG. 2(B)).
(C) Laser light L is irradiated to the side of the protective layer 33 to form grooves 34, which penetrate through the protective layer 33 and the resin layer 23, in a prescribed pattern (FIG. 2(C).
(D) The silicon substrate 21 is divided and singulated by dicing through the grooves 34 (FIG. 2(D)).
(E) After the dicing step, protective layers 33A are removed (FIG. 2(E)).

As a result, resin layer-equipped semiconductor chips 20A, in which a resin layer 23A is stacked on a singulated silicon substrate 21A and irregularities on the side surface (cut surface) of the silicon substrate 21A are reduced, are produced.

The above-described steps illustrated in FIG. 2 are one example of the method of producing a resin layer-equipped semiconductor chip according to the disclosure, and the disclosure is not limited thereto. For example, other steps such as the cleaning step may be incorporated as well.

The steps of the method of producing a resin layer-equipped semiconductor chip according to the disclosure will now each be described concretely. It is noted here that reference may be made to the drawings in the following description as well, but symbols are omitted as appropriate.

### [Laminated Body Preparation Step]

The method of producing a resin layer-equipped semiconductor chip according to the disclosure includes the laminated body preparation step of preparing the laminated body 20 in which the semiconductor substrate 21 and the resin layer 23 are stacked.

### (Semiconductor Substrate)

The material of the semiconductor substrate (hereinafter, may be simply referred to as “substrate”) is not particularly limited, and may be any material that is usually used, such as Si, InP, GaN, GaAs, InGaAs, InGaAlAs, or SiC.

The semiconductor substrates may each have a multi-layer structure. Examples of the multi-layer structure include: a structure in which an inorganic layer of silicon oxide, silicon nitride, SiCN (silicon carbonitride), or the like is formed on the surface of a silicon substrate or the like; a structure in which an organic layer of an organic-inorganic composite low-k material, such as a polyimide resin, a polybenzoxazole resin, an epoxy resin, CYCLOTENE (manufactured by The Dow Chemical Company), an imide-crosslinked siloxane resin, an epoxy-modified siloxane, a porous silica, an organic crosslinked siloxane, or BLACK DIAMOND (manufactured by Applied Materials, Inc.), is formed on the surface of a silicon substrate or the like; and a structure in which a composite of an inorganic substance and an organic substance is formed on a silicon substrate.

The thickness of each of the substrates is not particularly limited, and each of the substrates independently has a thickness of preferably from 0.5 μm to 1 mm, more preferably from 1 μm to 900 μm, still more preferably from 2 μm to 900 μm.

The shape of each of the substrates is also not particularly limited. For example, when the substrates are silicon substrates, the silicon substrates have an interlayer insulating layer (low-k film) formed thereon, and fine grooves (recesses), fine through-holes, and the like may be formed on the silicon substrates.

In the method of producing a resin layer-equipped semiconductor chip according to the disclosure, from the standpoint of the bonding strength, a surface treatment may be performed on the surfaces of the semiconductor substrates on a side coming into contact with a resin layer. By performing a surface treatment on the semiconductor substrates, at least one functional group selected from the group consisting of a hydroxy group, an epoxy group, a carboxy group, an amino group, and a mercapto group may be formed.

Examples of the surface treatment include a plasma treatment, a chemical treatment, and an ozone treatment such as an ultraviolet (UV) ozone treatment.

Hydroxy groups can be provided on the surfaces of the substrates by performing a surface treatment, for example, a plasma treatment, a chemical treatment, or an ozone treatment such as a UV-ozone treatment, on the surface of each substrate.

The surfaces of the substrates on a side coming into contact with a resin layer preferably have a silanol group containing a hydroxy group.

Epoxy groups can be provided on the surfaces of the substrates by performing a surface treatment such as silane coupling with epoxysilane on the surface of each substrate.

Carboxy groups can be provided on the surfaces of the substrates by performing a surface treatment such as silane coupling with carboxysilane on the surface of each substrate.

Amino groups can be provided on the surfaces of the substrates by performing a surface treatment such as silane coupling with aminosilane on the surface of each substrate.

Mercapto groups can be provided on the surfaces of the substrates by performing a surface treatment such as silane coupling with mercaptosilane on the surface of each substrate.

Further, from the standpoint of improving the bonding strength, a film of a primer such as a silane coupling agent may be formed on the surface of each substrate to which a resin material is applied.

### (Resin Layers)

Resin layers are each formed by applying a resin composition containing a resin material to one surface of the semiconductor substrate, and curing the thus formed resin composition layer.

The resin material contained in the resin composition is not particularly limited, and examples thereof include: materials in which a bond or a structure is formed by crosslinking, such as polyimide, polyamide, polyamideimide, parylene, polyarylene ether, tetrahydronaphthalene, and octahydroanthracene; materials in which a nitrogen ring-containing structure is formed, such as polybenzoxazole and polybenzoxazine; materials in which a bond or a structure, such as Si—O, is formed by crosslinking; and organic materials such as siloxane-modified compounds.

The resin materials used for the formation of the resin layers may be the same or different.

Examples of a structure having a Si—O bond (siloxane bond) include structures represented by the following Formulae (1) to (3).

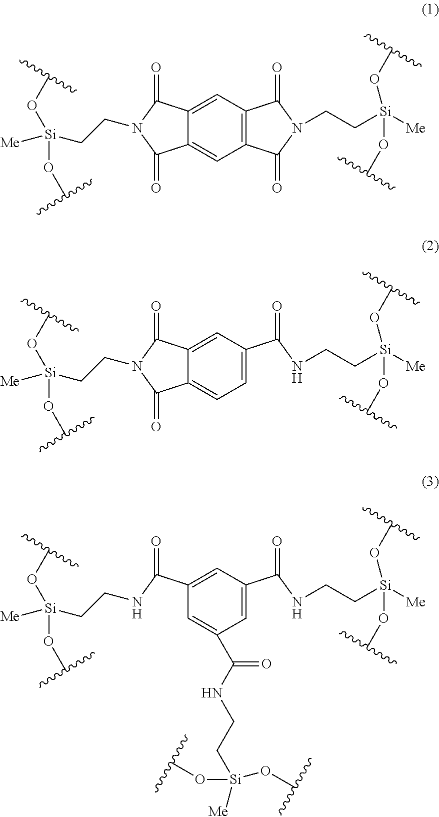 [SMILES: *O[Si](C)(CCn1c(=O)c2cc3c(=O)n(CC[Si](C)(O*)O*)c(=O)c3cc2c1=O)O* ; *O[Si](C)(CCNC(=O)c1ccc2c(c1)C(=O)N(CC[Si](C)(O*)O*)C2=O)O* ; *O[Si](C)(CCNC(=O)c1cc(C(=O)NCC[Si](C)(O*)O*)cc(C(=O)NCC[Si](C)(O*)O*)c1)O*]

In these structures having a Si—O bond (siloxane bond), a group bound to Si may be substituted with an alkylene group, a phenylene group, or the like. For example, such structures may have (—O—)ₓ(R₁)_{y}Si—(R₂)—Si(R₁)_{y}(—O—)ₓ or the like (wherein, R₁ represents a methyl group or the like; R₂ represents an alkylene group, a phenylene group, or the like; each of x and y independently represents an integer of 0 or larger; and x+y=3).

Examples of a material in which a Si—O bond is formed by crosslinking include compounds represented by the following Formulae (4) and (5). The structures represented by Formulae (1) and (2) can be generated by, for example, heating and reacting the compounds represented by the following Formulae (4) and (5), respectively.

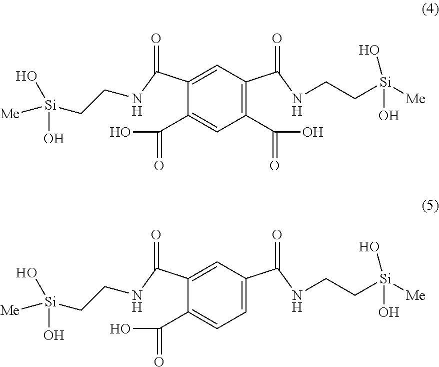 [SMILES: C[Si](O)(O)CCNC(=O)c1cc(C(=O)NCC[Si](C)(O)O)c(C(=O)O)cc1C(=O)O ; C[Si](O)(O)CCNC(=O)c1ccc(C(=O)O)c(C(=O)NCC[Si](C)(O)O)c1]

For example, when the resin material contains a material in which a bond or a structure is formed by crosslinking, such as polyimide, polyamide, or polyamideimide, the resin material preferably contains: a compound (A) that has a cationic functional group containing at least one of a primary nitrogen atom or a secondary nitrogen atom, and has a weight-average molecular weight of from 90 to 400,000; and a crosslinking agent (B) having three or more —C(═O)OX groups (wherein, X represents a hydrogen atom or an alkyl group having from 1 to 6 carbon atoms) in the molecule, in which from one to six of the three or more —C(═O)OX groups are —C(═O)OH groups, and which has a weight-average molecular weight of from 200 to 2,000.

### (Compound (A))

The compound (A) is a compound that has a cationic functional group containing at least one of a primary nitrogen atom or a secondary nitrogen atom, and has a weight-average molecular weight of from 90 to 400,000. The cationic functional group is not particularly limited as long as it is a functional group that can bear a positive charge and contains at least one of a primary nitrogen atom or a secondary nitrogen atom.

The compound (A) may also contain a tertiary nitrogen atom in addition to the primary nitrogen atom and the secondary nitrogen atom.

In the disclosure, a “primary nitrogen atom” refers to a nitrogen atom that is bonded to only two hydrogen atoms and one atom other than a hydrogen atom (e.g., a nitrogen atom contained in a primary amino group (—NH₂ group)), or a nitrogen atom (cation) that is bonded to only three hydrogen atoms and one atom other than a hydrogen atom.

A “secondary nitrogen atom” refers to a nitrogen atom that is bonded to only one hydrogen atom and two atoms other than a hydrogen atom (i.e., a nitrogen atom contained in a functional group represented by the following Formula (a)), or a nitrogen atom (cation) that is bonded to only two hydrogen atoms and two atoms other than a hydrogen atom.

Further, a “tertiary nitrogen atom” refers to a nitrogen atom that is bonded to only three atoms other than a hydrogen atom (i.e., a nitrogen atom that is a functional group represented by the following Formula (b)), or a nitrogen atom (cation) that is bonded to only one hydrogen atom and three atoms other than a hydrogen atom.

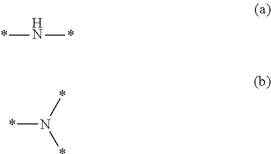

In Formulae (a) and (b), * represents a position of binding with an atom other than a hydrogen atom.

The functional group represented by Formula (a) may be a functional group constituting a part of a secondary amino group (—NHR^{a} group, wherein R^{a} represents an alkyl group), or may be a divalent linking group contained in a polymer skeleton.

The functional group represented by Formula (b) (i.e., a tertiary nitrogen atom) may be a functional group constituting a part of a tertiary amino group (—NR^{b}R^{c} group, wherein each of R^{b} and R^{c} independently represents an alkyl group), or may be a trivalent linking group contained in a polymer skeleton.

The compound (A) has a weight-average molecular weight of from 90 to 400,000. Examples of the compound (A) include aliphatic amines, compounds having a siloxane bond (Si—O bond) and an amino group, and amine compounds having a ring structure without a Si—O bond in the molecule. When the compound (A) is an aliphatic amine, the weight-average molecular weight thereof is preferably from 10,000 to 200,000. When the compound (A) is a compound having a siloxane bond (Si—O bond) and an amino group, the weight-average molecular weight thereof is preferably from 130 to 10,000, more preferably from 130 to 5,000, still more preferably from 130 to 2,000. When the compound (A) is an amine compound having a ring structure without a Si—O bond in the molecule, the weight-average molecular weight thereof is preferably from 90 to 600.

In the disclosure, the weight-average molecular weight refers to a weight-average molecular weight in terms of polyethylene glycol, which is measured by gel permeation chromatography (GPC) for a compound other than a monomer.

Specifically, the weight-average molecular weight is determined by detecting the refractive index at a flow rate of 1.0 mL/min using an aqueous solution of sodium nitrate having a concentration of 0.1 mol/L as a developing solvent and an analyzer SHODEX DET RI-101 along with two kinds of analytical columns (TSKgel G6000PWXL-CP and TSKgel G3000PWXL-CP, manufactured by Tosoh Corporation), and performing calculation using an analysis software (EMPOWER3, manufactured by Waters Corporation) and polyethylene glycol/polyethylene oxide as a standard.

If necessary, the compound (A) may further have an anionic functional group, a nonionic functional group, or the like.

The nonionic functional group may be a hydrogen bond acceptor or a hydrogen bond donor. Examples of the nonionic functional group include a hydroxy group, a carbonyl group, and an ether group (—O—).

The anionic functional group is not particularly limited as long as it is a functional group that can bear a negative charge. Examples of the anionic functional group include a carboxylic acid group, a sulfonic acid group, and a sulfuric acid group.

Examples of the compound (A) include aliphatic amines, more specifically: polyalkyleneimines that are polymers of alkyleneimines, such as ethyleneimine, propyleneimine, butyleneimine, pentyleneimine, hexyleneimine, heptyleneimine, octyleneimine, trimethyleneimine, tetramethyleneimine, pentamethyleneimine, hexamethyleneimine, and octamethyleneimine; polyallylamines; and polyacrylamides.

A polyethyleneimine (PEI) can be produced by any known method described in, for example, Japanese Patent Publication (JP-B) No. S43-8828, JP-B No. S49-33120, JP-A No. 2001-213958, or WO 2010/137711. A polyalkyleneimine other than a polyethyleneimine can also be produced by the same method as a polyethyleneimine.

The compound (A) is also preferably a derivative of any of the aforementioned polyalkyleneimines (a polyalkyleneimine derivative; particularly preferably a polyethyleneimine derivative). The polyalkyleneimine derivative is not particularly limited as long as it is a compound that can be produced using any of the aforementioned polyalkyleneimines. Specific examples of the polyalkyleneimine derivative include: polyalkyleneimine derivatives obtained by introducing an alkyl group (preferably an alkyl group having from 1 to 10 carbon atoms), an aryl group, or the like into a polyalkyleneimine; and polyalkyleneimine derivatives obtained by introducing a crosslinkable group such as a hydroxy group into a polyalkyleneimine.

These polyalkyleneimine derivatives can be produced by a method that is usually performed using any of the aforementioned polyalkyleneimines. Specifically, the polyalkyleneimine derivatives can be produced, for example, in accordance with the method described in JP-A No. H6-016809 or the like.

As the polyalkyleneimine derivative, a highly branched polyalkyleneimine obtained by allowing a cationic functional group-containing monomer to react with a polyalkyleneimine and thereby improving the branching degree of the polyalkyleneimine is also preferred.

Examples of a method of obtaining a highly branched polyalkyleneimine include: a method of allowing a cationic functional group-containing monomer to react with a polyalkyleneimine having plural secondary nitrogen atoms in its skeleton, and thereby substituting at least one of the plural secondary nitrogen atoms with the cationic functional group-containing monomer; and a method of allowing a cationic functional group-containing monomer to react with a polyalkyleneimine having plural primary nitrogen atoms at its terminals, and thereby substituting at least one of the plural primary nitrogen atoms with the cationic functional group-containing monomer.

Examples of the cationic functional group introduced to improve the branching degree include an aminoethyl group, an aminopropyl group, a diaminopropyl group, an aminobutyl group, a diaminobutyl group, and a triaminobutyl group; however, from the standpoint of reducing the equivalent of the cationic functional group and increasing the density of the cationic functional group, an aminoethyl group is preferred.

The above-described polyethyleneimine and derivatives thereof may be commercially available products. The polyethyleneimine and derivatives thereof may be selected as appropriate from those that are commercially available from, for example, Nippon Shokubai Co., Ltd., BASF SE, and MP Biomedicals, LLC.

Examples of the compound (A) include compounds having a Si—O bond and an amino group, in addition to the above-described aliphatic amines. Examples of the compounds having a Si—O bond and an amino group include siloxanediamines, amino group-containing silane coupling agents, and siloxane polymers of amino group-containing silane coupling agents.

Examples of the amino group-containing silane coupling agents include compounds represented by the following Formula (A-3).

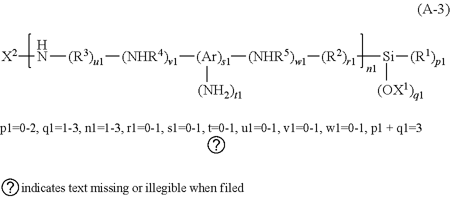

In Formula (A-3), R¹ represents an optionally substituted alkyl group having from 1 to 4 carbon atoms; each of R² and R³ independently represents an optionally substituted alkylene group having from 1 to 12 carbon atoms (optionally containing a carbonyl group, an ether group, or the like in the skeleton), an ether group, or a carbonyl group; each of R⁴ and R⁵ independently represents an optionally substituted alkylene group having from 1 to 4 carbon atoms, or a single bond; Ar represents a divalent or trivalent aromatic ring; X¹ represents hydrogen or an optionally substituted alkyl group having from 1 to 5 carbon atoms; X² represents hydrogen, a cycloalkyl group, a heterocyclic group, an aryl group, or an optionally substituted alkyl group having from 1 to 5 carbon atoms (optionally containing a carbonyl group, an ether group, or the like in the skeleton); and plural R¹s, R²s, R³s, R⁴s, R⁵s, and X¹s may be the same or different.

Each of the substituents of the alkyl groups and the alkylene groups that are represented by R¹, R², R³, R⁴, R⁵, X¹, and X² may independently be, for example, an amino group, a hydroxy group, an alkoxy group, a cyano group, a carboxylic acid group, a sulfonic acid group, or a halogen.

Examples of the divalent or trivalent aromatic ring represented by Ar include a divalent or trivalent benzene ring. Examples of the aryl group represented by X² include a phenyl group, a methylbenzyl group, and a vinylbenzyl group.

Specific examples of the silane coupling agent represented by Formula (A-3) include N-(2-aminoethyl)-3-aminopropylmethyldiethoxysilane, N-(2-aminoethyl)-3-aminopropyltriethoxysilane, N-(2-aminoethyl)-3-aminoisobutyldimethylmethoxysilane, N-(2-aminoethyl)-3-aminoisobutylmethyldimethoxysilane, N-(2-aminoethyl)-11-aminoundecyltrimethoxysilane, 3-aminopropyltrimethoxysilane, 3-aminopropyltriethoxysilane, N-phenyl-3-aminopropyltrimethoxysilane, (aminoethylaminoethyl)phenyltriethoxysilane, methylbenzylaminoethylaminopropyltrimethoxysilane, benzylaminoethylaminopropyltriethoxysilane, 3-ureidopropyltriethoxysilane, (aminoethylaminoethyl)phenethyltrimethoxysilane, (aminoethylaminomethyl)phenethyltrimethoxysilane, N-[2-[3-(trimethoxysilyl)propylamino]ethyl]ethylenediamine, 3-aminopropyldiethoxymethylsilane, 3-aminopropyldimethoxymethylsilane, 3-aminopropyldimethylethoxysilane, 3-aminopropyldimethylmethoxysilane, trimethoxy[2-(2-aminoethyl)-3-aminopropyl]silane, diaminomethylmethyldiethoxysilane, methylaminomethylmethyldiethoxysilane, p-aminophenyltrimethoxysilane, N-methylaminopropyltriethoxysilane, N-methylaminopropylmethyldiethoxysilane, (phenylaminomethyl)methyldiethoxysilane, acetamidopropyltrimethoxysilane, and hydrolysates thereof.

Examples of an amino group-containing silane coupling agent other than that of Formula (A-3) include N,N-bis[3-(trimethoxysilyl)propyl]ethylenediamine, N,N-bis[3-(trimethoxysilyl)propyl]ethylenediamine, bis[(3-triethoxysilyl)propyl]amine, piperazinylpropylmethyldimethoxysilane, bis[3-(triethoxysilyl)propyl]urea, bis(methyldiethoxysilylpropyl)amine, 2,2-dimethoxy-1,6-diaza-2-silacyclooctane, 3,5-diamino-N-(4-(methoxydimethylsilyl)phenyl)benzamide, 3,5-diamino-N-(4-(triethoxysilyl)phenyl)benzamide, 5-(ethoxydimethylsilyl)benzene-1,3-diamine, and hydrolysates thereof.

The above-described amino group-containing silane coupling agents may be used singly, or in combination of two or more kinds thereof. Further, the amino group-containing silane coupling agents may be used in combination with a silane coupling agent that does not have an amino group. For example, a mercapto group-containing silane coupling agent may be used for the purpose of improving the adhesion with a metal.

A polymer (siloxane polymer) formed from any of these silane coupling agents via a siloxane bond (Si—O—Si) may be used as well. For example, from a hydrolysate of 3-aminopropyltrimethoxysilane, a polymer having a linear siloxane structure, a polymer having a branched siloxane structure, a polymer having a cyclic siloxane structure, a polymer having a cage-like siloxane structure, or the like can be obtained. The cage-like siloxane structure is represented by, for example, the following Formula (A-1).

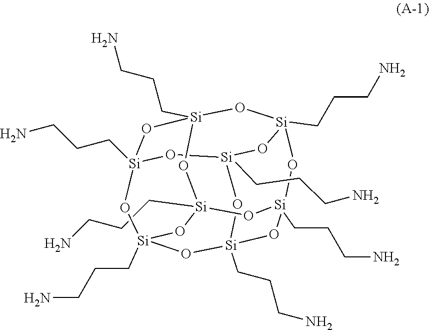 [SMILES: NCCC[Si]12O[Si]3(CCCN)O[Si]4(CCCN)O[Si](CCCN)(O1)O[Si]1(CCCN)O[Si](CCCN)(O2)O[Si](CCCN)(O3)O[Si](CCCN)(O4)O1]

Examples of the siloxanediamines include compounds represented by the following Formula (A-2). In Formula (A-2), i represents an integer from 0 to 4, j represents an integer from 1 to 3, and Me represents a methyl group.

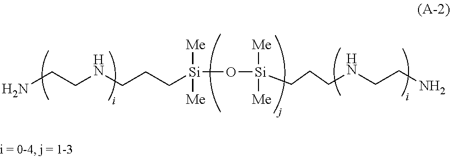

Examples of the siloxanediamines include 1,3-bis(3-aminopropyl)tetramethyldisiloxane (in Formula (A-2), i=0 and j=1) and 1,3-bis(2-aminoethylamino)propyltetramethyldisiloxane (in Formula (A-2), i=1 and j=1).

Examples of the compound (A) include amine compounds having a ring structure without a Si—O bond in the molecule, in addition to the above-described aliphatic amines and compounds having a Si—O bond and an amino group. Thereamong, those amine compounds having a ring structure without a Si—O bond in the molecule that have a weight-average molecular weight of from 90 to 600, are preferred. Examples of the amine compounds having a ring structure without a Si—O bond in the molecule that have a weight-average molecular weight of from 90 to 600 include alicyclic amines, aromatic amines, and heterocyclic amines. These amine compounds may each have plural ring structures in the molecule, and the plural ring structures may be the same or different. The amine compounds having a ring structure are more preferably compounds having an aromatic ring since they are likely to provide thermally more stable compounds.

Further, the amine compounds having a ring structure without a Si—O bond in the molecule that have a weight-average molecular weight of from 90 to 600 are preferably compounds having a primary amino group since they easily form a thermally crosslinked structure, such as amide, amideimide, or imide, together with the crosslinking agent (B), and can thus improve the heat resistance. Moreover, the above-described amine compounds are preferably diamine compounds having two primary amino groups, triamine compounds having three primary amino groups, or the like since they easily increase the number of thermally crosslinked structures, such as amide, amideimide, and imide, together with the crosslinking agent (B), and can thus further improve the heat resistance.

Examples of the alicyclic amines include cyclohexylamine and dimethylaminocyclohexane.

Examples of the aromatic amines include diaminodiphenyl ether, xylenediamine (preferably p-xylenediamine), diaminobenzene, diaminotoluene, methylenedianiline, dimethyldiaminobiphenyl, bis(trifluoromethyl)diaminobiphenyl, diaminobenzophenone, diaminobenzanilide, bis(aminophenyl) fluorene, bis(aminophenoxy)benzene, bis(aminophenoxy)biphenyl, dicarboxydiaminodiphenylmethane, diaminoresorcin, dihydroxybenzidine, diaminobenzidine, 1,3,5-triaminophenoxybenzene, 2,2′-dimethylbenzidine, tris(4-aminophenyl)amine, 2,7-diaminofluorene, 1,9-diaminofluorene, and dibenzylamine.

Examples of the heterocycles of the heterocyclic amines include heterocycles containing a sulfur atom as a heteroatom (e.g., a thiophene ring), and heterocycles containing a nitrogen atom as a heteroatom (e.g., 5-membered rings, such as a pyrrole ring, a pyrrolidine ring, a pyrazole ring, an imidazole ring, and a triazole ring; 6-membered rings, such as an isocyanuric ring, a pyridine ring, a pyridazine ring, a pyrimidine ring, a pyrazine ring, a piperidine ring, a piperazine ring, and a triazine ring; and condensed rings, such as an indole ring, an indoline ring, a quinoline ring, an acridine ring, a naphthyridine ring, a quinazoline ring, a purine ring, and a quinoxaline ring).

Examples of a heterocyclic amine having a nitrogen-containing heterocycle include melamine, ammeline, melam, melem, and tris(4-aminophenyl)amine.

Examples of an amine compound having both a heterocycle and an aromatic ring include N2,N4,N6-tris(4-aminophenyl)-1,3,5-triazine-2,4,6-triamine.

Since the compound (A) has a primary or secondary amino group, the compound (A) can strongly bond the first and the second substrates to each other by electrostatically interacting with the functional groups such as hydroxy groups, epoxy groups, carboxy groups, amino groups, and mercapto groups that may exist on the surfaces of the first and the second substrates, or by densely forming covalent bonds with the functional groups.

Further, since the compound (A) has a primary or secondary amino group, the compound (A) is readily dissolved in the below-described polar solvent (D). By using the compound (A) that is readily dissolved in the polar solvent (D), the affinity thereof with the hydrophilic surface of a substrate such as a silicon substrate is increased, so that a smooth film is likely to be formed and the thickness of each resin layer can be reduced.

The compound (A) is preferably an aliphatic amine or a compound having a Si—O bond and an amino group from the standpoint of forming a smooth thin film, more preferably a compound having a Si—O bond and an amino group from the standpoint of heat resistance.

When the compound (A) contains a compound having a Si—O bond and an amino group, from the standpoint of forming a smooth thin film, the ratio between a total number of primary and secondary nitrogen atoms and the number of silicon atoms in the compound (A) (total number of primary and secondary nitrogen atoms/number of silicon atoms) is preferably from 0.2 to 5.

When the compound (A) contains a compound having a Si—O bond and an amino group, from the standpoint of adhesion between the substrates, it is preferred that, in the compound having a Si—O bond and an amino group, non-crosslinkable groups such as a methyl group bound to Si satisfy a relationship of (non-crosslinkable group)/Si<2 in terms of molar ratio. It is presumed that, by satisfying this relationship, the density of crosslinks (crosslinks between a Si—O—Si bond and an amide bond, an imide bond, or the like) in the resulting film is improved and the substrates have a sufficient adhesive strength, so that peeling of the substrates can be inhibited.

As described above, the compound (A) has a cationic functional group containing at least one of a primary nitrogen atom or a secondary nitrogen atom. When the compound (A) contains a primary nitrogen atom, the ratio of the primary nitrogen atom in all nitrogen atoms in the compound (A) is preferably 20% by mole or more, more preferably 25% by mole or more, still more preferably 30% by mole or more. The compound (A) may have a cationic functional group that contains a primary nitrogen atom but does not contain a nitrogen atom other than the primary nitrogen atom (e.g., a secondary nitrogen atom or a tertiary nitrogen atom).

When the compound (A) contains a secondary nitrogen atom, the ratio of the secondary nitrogen atom in all nitrogen atoms in the compound (A) is preferably from 5% by mole to 50% by mole, more preferably from 10% by mole to 45% by mole.

The compound (A) may also contain a tertiary nitrogen atom in addition to a primary nitrogen atom and a secondary nitrogen atom and, when the compound (A) contains a tertiary nitrogen atom, the ratio of the tertiary nitrogen atom in all nitrogen atoms in the compound (A) is preferably from 20% by mole to 50% by mole, more preferably from 25% by mole to 45% by mole.

In the disclosure, the content of a component derived from the compound (A) in each resin layer is not particularly limited and may be, for example, from 1% by mass to 82% by mass with respect to the whole resin layer, and it is preferably from 5% by mass to 82% by mass, more preferably from 13% by mass to 82% by mass.

### (Crosslinking Agent (B))

The crosslinking agent (B) is a compound which contains three or more —C(═O)OX groups (wherein, X represents a hydrogen atom or an alkyl group having from 1 to 6 carbon atoms) in the molecule and has a weight-average molecular weight of from 200 to 2,000, and in which one to six of the three or more —C(═O)OX groups (hereinafter, also referred to as “COOX”) are —C(═O)OH groups (hereinafter, also referred to as “COOH”).

The crosslinking agent (B) is a compound having three or more-C(═O)OX groups (wherein, X represents a hydrogen atom or an alkyl group having from 1 to 6 carbon atoms) in the molecule, preferably a compound having from three to six —C(═O)OX groups in the molecule, more preferably a compound having three or four —C(═O)OX groups in the molecule.

In the crosslinking agent (B), examples of X in each —C(═O)OX group include a hydrogen atom and alkyl groups having from 1 to 6 carbon atoms, among which a hydrogen atom, a methyl group, an ethyl group, and a propyl group are preferred. It is noted here that Xs in the —C(═O)OX groups may be the same or different from each other.

The crosslinking agent (B) is a compound having from one to six —C(═O)OH groups, in which X is a hydrogen atom, in the molecule, preferably a compound having from one to four —C(═O)OH groups in the molecule, more preferably a compound having from two to four —C(═O)OH groups in the molecule, still more preferably a compound having two or three —C(═O)OH groups in the molecule.

The crosslinking agent (B) is a compound having a weight-average molecular weight of from 200 to 2,000. The weight-average molecular weight of the crosslinking agent (B) is preferably from 200 to 1,000, more preferably from 200 to 600, still more preferably from 200 to 400.

The crosslinking agent (B) preferably has a ring structure in the molecule. The ring structure may be, for example, an alicyclic structure or an aromatic ring structure. The crosslinking agent (B) may have plural ring structures in the molecule, and the plural ring structures may be the same or different.

Examples of the alicyclic structure include alicyclic structures having from 3 to 8 carbon atoms, preferably alicyclic structures having from 4 to 6 carbon atoms, in which the ring structures may be saturated or unsaturated. More specific examples of the alicyclic structure include: saturated alicyclic structures, such as a cyclopropane ring, a cyclobutane ring, a cyclopentane ring, a cyclohexane ring, a cycloheptane ring, and a cyclooctane ring; and unsaturated alicyclic structures, such as a cyclopropene ring, a cyclobutene ring, a cyclopentene ring, a cyclohexene ring, a cycloheptene ring, and a cyclooctene ring.

The aromatic ring structure is not particularly limited as long as it is a ring structure exhibiting aromaticity, and examples thereof include: benzene aromatic rings, such as a benzene ring, a naphthalene ring, an anthracene ring, and a perylene ring; aromatic heterocyclic rings, such as a pyridine ring and a thiophene ring; and non-benzene aromatic rings, such as an indene ring and an azulene ring.

The ring structure contained in the molecule of the crosslinking agent (B) is preferably, for example, at least one selected from the group consisting of a cyclobutane ring, a cyclopentane ring, a cyclohexane ring, a benzene ring, and a naphthalene ring and, from the standpoint of further improving the heat resistance of each resin layer, at least one of a benzene ring or a naphthalene ring is more preferred.

As described above, the crosslinking agent (B) may have plural ring structures in the molecule and, when the ring structures are benzene, the crosslinking agent (B) may have a biphenyl structure, a benzophenone structure, a diphenyl ether structure, and the like.

The crosslinking agent (B) preferably has a fluorine atom in the molecule, more preferably has from 1 to 6 fluorine atoms in the molecule, still more preferably has from 3 to 6 fluorine atoms in the molecule. For example, the crosslinking agent (B) may have a fluoroalkyl group, specifically a trifluoroalkyl group or a hexafluoroisopropyl group, in the molecule.

Examples of the crosslinking agent (B) include: carboxylic acid compounds, such as alicyclic carboxylic acids, benzene carboxylic acids, naphthalene carboxylic acids, diphthalic acids, and fluorinated aromatic carboxylic acids; and carboxylic acid ester compounds, such as alicyclic carboxylic acid esters, benzene carboxylic acid esters, naphthalene carboxylic acid esters, diphthalic acid esters, and fluorinated aromatic carboxylic acid esters. The carboxylic acid ester compounds are compounds which have a carboxy group (—C(═O)OH group) in the molecule, and in which at least one X in three or more —C(═O)OX groups is an alkyl group having from 1 to 6 carbon atoms (i.e., the compounds have an ester bond). In the disclosure, when the crosslinking agent (B) is a carboxylic acid ester compound, the aggregation caused by association of the compound (A) and the crosslinking agent (B) is inhibited, and the amount of aggregates and pits is thus reduced, so that the film thickness can be easily adjusted.

The above-described carboxylic acid compounds are preferably tetravalent or lower valent carboxylic acid compounds containing four or less —C(═O)OH groups, more preferably trivalent or tetravalent carboxylic acid compounds containing three or four —C(═O)OH groups.

The above-described carboxylic acid ester compounds are preferably compounds containing three or less carboxy groups (—C(═O)OH groups) and three or less ester bonds in the molecule, more preferably compounds containing two or less carboxy groups and two or less ester bonds in the molecule.

In the carboxylic acid ester compounds, when Xs in the three or more —C(═O)OX groups are alkyl groups having from 1 to 6 carbon atoms, Xs are each preferably a methyl group, an ethyl group, a propyl group, a butyl group, or the like and, from the standpoint of further inhibiting the aggregation caused by association of the compound (A) and the crosslinking agent (B), Xs are each preferably an ethyl group or a propyl group.

Specific examples of the carboxylic acid compounds include, but not limited to: alicyclic carboxylic acids, such as 1,2,3,4-cyclobutanetetracarboxylic acid, 1,2,3,4-cyclopentanetetracarboxylic acid, 1,3,5-cyclohexanetricarboxylic acid, 1,2,4-cyclohexanetricarboxylic acid, 1,2,4,5-cyclohexanetetracarboxylic acid, and 1,2,3,4,5,6-cyclohexanehexacarboxylic acid; benzene carboxylic acids, such as 1,2,4-benzenetricarboxylic acid, 1,3,5-benzene tricarboxylic acid, pyromellitic acid, 3,4′-biphthalic acid, p-phenylene-bis(trimellitic acid), benzenepentacarboxylic acid, and mellitic acid; naphthalene carboxylic acids, such as 1,4,5,8-naphthalenetetracarboxylic acid and 2,3,6,7-naphthalenetetracarboxylic acid; diphthalic acids, such as 3,3′,5,5′-tetracarboxydiphenylmethane, biphenyl-3,3′,5,5′-tetracarboxylic acid, biphenyl-3,4′,5-tricarboxylic acid, biphenyl-3,3′,4,4′-tetracarboxylic acid, benzophenone-3,3′,4,4′-tetracarboxylic acid, 4,4′-oxydiphthalic acid, 3,4′-oxydiphthalic acid, 1,3-bis(phthalic acid) tetramethyldisiloxane, 4,4′-(ethyne-1,2-diyl)diphthalic acid, 4,4′-(1,4-phenylenebis(oxy)) diphthalic acid, 4,4′-([1,1′-biphenyl]-4,4′-diylbis(oxy))diphthalic acid, and 4,4′-((oxybis(4,1-phenylene))bis(oxy))diphthalic acid; perylene carboxylic acids, such as perylene-3,4,9,10-tetracarboxylic acid; anthracene carboxylic acids, such as anthracene-2,3,6,7-tetracarboxylic acid; and fluorinated aromatic carboxylic acids, such as 4,4′-(hexafluoroisopropylidene)diphthalic acid, 9,9-bis(trifluoromethyl)-9H-xanthene-2,3,6,7-tetracarboxylic acid, and 1,4-ditrifluoromethyl pyromellitic acid.

Specific examples of the carboxylic acid ester compounds include those compounds described above as specific examples of the carboxylic acid compounds, in which at least one carboxy group is substituted with an ester group. The carboxylic acid ester compounds are, for example, half-esterified compounds represented by the following Formulae (B-1) to (B-5).

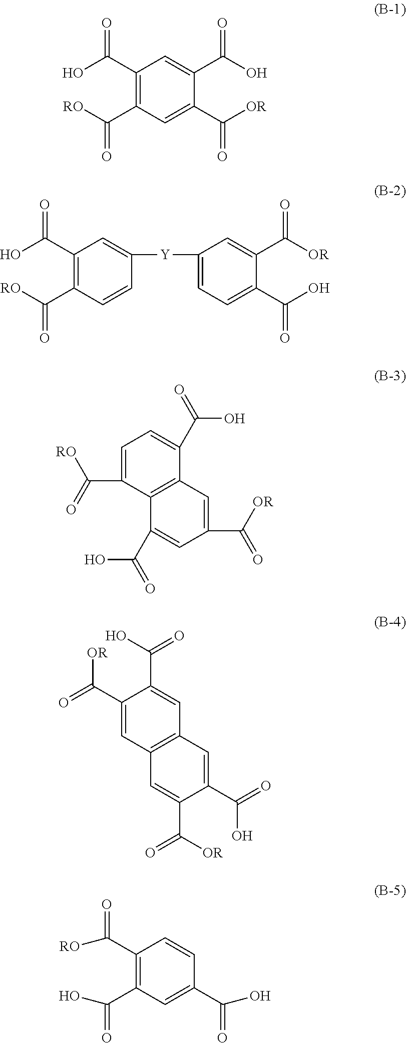

In Formulae (B-1) to (B-5), each of Rs independently represents an alkyl group having from 1 to 6 carbon atoms and, particularly, Rs are each preferably a methyl group, an ethyl group, a propyl group, or a butyl group, more preferably an ethyl group or a propyl group.

In Formula (B-2), Y represents a single bond, O, C═O, or C(CF₃)₂.

The half-esterified compounds can be generated by, for example, mixing carboxylic anhydrides that are anhydrides of the above-described carboxylic acid compounds in an alcohol solvent, and ring-opening the carboxylic acid anhydrides.

In the disclosure, the content of a component derived from the crosslinking agent (B) in each resin layer is not particularly limited and, for example, a ratio (—(C═O)—Y)/N) of the number of carbonyl groups (—(C═O)—Y) in a substance derived from the crosslinking agent (B) with respect to the number of all nitrogen atoms in a substance derived from the compound (A) is preferably from 0.1 to 3.0, more preferably from 0.3 to 2.5, still more preferably from 0.4 to 2.2. In —(C═O)—Y, Y represents an imide-crosslinked or amide-crosslinked nitrogen atom, OH, or an ester group. When the ratio (—(C═O)—Y)/N is from 0.1 to 3.0, the resin layer suitably has a crosslinked structure such as amide, amideimide, or imide, and exhibits superior heat resistance.

### (Polar Solvent (D))

In the laminated body preparation step, a resin composition containing a resin material may be applied to at least one surface of a substrate. In this case, the resin composition containing a resin material preferably contains a polar solvent (D) along with the above-described resin materials such as the compound (A) and the crosslinking agent (B). The polar solvent (D) refers to a solvent having a relative permittivity of 5 or more at room temperature. Specific examples of the polar solvent (D) include: protic inorganic compounds, such as water and heavy water; alcohols, such as methanol, ethanol, 1-propanol, 2-propanol, 1-butanol, 2-butanol, isobutyl alcohol, isopentyl alcohol, cyclohexanol, ethylene glycol, propylene glycol, 2-methoxyethanol, 2-ethoxyethanol, benzyl alcohol, diethylene glycol, triethylene glycol, and glycerin; ethers, such as tetrahydrofuran and dimethoxyethane; aldehydes and ketones, such as furfural, acetone, ethyl methyl ketone, and cyclohexane; acid derivatives, such as acetic anhydride, ethyl acetate, butyl acetate, ethylene carbonate, propylene carbonate, formaldehyde, N-methylformamide, N,N-dimethylformamide, N-methylacetamide, N,N-dimethylacetamide, N-methyl-2-pyrrolidone, and hexamethylphosphoramide; nitriles, such as acetonitrile and propionitrile; nitro compounds, such as nitromethane and nitrobenzene; and sulfur compounds such as dimethyl sulfoxide. The polar solvent (D) preferably contains a protic solvent, more preferably water, still more preferably ultrapure water.

The content of the polar solvent (D) in the resin composition is not particularly limited and is, for example, from 1.0% by mass to 99.99896% by mass, preferably from 40% by mass to 99.99896% by mass, with respect to the whole resin composition.

From the standpoint of volatilizing the polar solvent (D) by heating at the time of forming a resin layer and thereby reducing the amount of residual solvent in the resulting resin layer, the polar solvent (D) has a boiling point of preferably 150° C. or lower, more preferably 120° C. or lower.

### (Additive (C))

The resin composition containing a resin material may also contain an additive (C) in addition to the above-described resin materials such as the compound (A) and the crosslinking agent (B), the polar solvent (D), and the like. Examples of the additive (C) include an acid (C-1) that contains a carboxy group and has a weight-average molecular weight of from 46 to 195, and a base (C-2) that contains a nitrogen atom with no ring structure and has a weight-average molecular weight of from 17 to 120. Although the additive (C) is volatilized by heating at the time of forming a resin layer, the resin layer in the substrate laminated body of the disclosure may contain the additive (C).

The acid (C-1) is an acid that contains a carboxy group and has a weight-average molecular weight of from 46 to 195. It is presumed that, when the acid (C-1) is incorporated as the additive (C), the amino group of the compound (A) and the carboxy group of the acid (C-1) form an ionic bond, and the aggregation caused by association of the compound (A) and the crosslinking agent (B) is thereby inhibited. More specifically, it is presumed that the aggregation is inhibited since the interaction (e.g., electrostatic interaction) between an ammonium ion derived from the amino group of the compound (A) and a carboxylate ion derived from the carboxy group of the acid (C-1) is stronger than the interaction between the ammonium ion derived from the amino group of the compound (A) and a carboxylate ion derived from the carboxy group of the crosslinking agent (B). It is noted here, however, that the disclosure is not limited at all by the above presumption.

The acid (C-1) is not particularly limited as long as it contains a carboxy group and has a weight-average molecular weight of from 46 to 195, and examples thereof include monocarboxylic acid compounds, dicarboxylic acid compounds, and oxydicarboxylic acid compounds. More specific examples of the acid (C-1) include formic acid, acetic acid, malonic acid, oxalic acid, citric acid, benzoic acid, lactic acid, glycolic acid, glyceric acid, butyric acid, methoxyacetic acid, ethoxyacetic acid, phthalic acid, terephthalic acid, picolinic acid, salicylic acid, and 3,4,5-trihydroxybenzoic acid.

In the disclosure, the content of the acid (C-1) in the resin composition containing a resin material is not particularly limited and, for example, a ratio (COOH/N) of the number of carboxy groups in the acid (C-1) with respect to the number of all nitrogen atoms in the compound (A) is preferably from 0.01 to 10, more preferably from 0.02 to 6, still more preferably from 0.5 to 3.

The base (C-2) is a base that contains a nitrogen atom and has a weight-average molecular weight of from 17 to 120. It is presumed that, when the resin composition containing a resin material contains the base (C-2) as the additive (C), the carboxy group of the crosslinking agent (B) and the amino group of the base (C-2) form an ionic bond, and the aggregation caused by association of the compound (A) and the crosslinking agent (B) is thereby inhibited. More specifically, it is presumed that the aggregation is inhibited since the interaction between a carboxylate ion derived from the carboxy group of the crosslinking agent (B) and an ammonium ion derived from the amino group of the base (C-2) is stronger than the interaction between an ammonium ion derived from the amino group of the compound (A) and the carboxylate ion derived from the carboxy group of the crosslinking agent (B). It is noted here, however, that the disclosure is not limited at all by the above presumption.

The base (C-2) is not particularly limited as long as it contains a nitrogen atom with no ring structure and has a weight-average molecular weight of from 17 to 120, and examples thereof include monoamine compounds and diamine compounds. More specific examples of the base (C-2) include ammonia, ethylamine, ethanolamine, diethylamine, triethylamine, ethylenediamine, N-acetylethylenediamine, N-(2-aminoethyl) ethanolamine, and N-(2-aminoethyl)glycine.

In the disclosure, the content of the base (C-2) in the resin composition containing a resin material is not particularly limited and, for example, a ratio (N/COOH) of the number of nitrogen atoms in the base (C-2) with respect to the number of carboxy groups in the crosslinking agent (B) is preferably from 0.5 to 5, more preferably from 0.9 to 3.

When the resin layer of the substrate laminated body of the disclosure is required to have an insulating property, tetraethoxysilane, tetramethoxysilane, bis-triethoxysilylethane, bis-triethoxysilylmethane, bis(methyldiethoxysilyl) ethane, 1,1,3,3,5,5-hexaethoxy-1,3,5-trisilacyclohexane, 1,3,5,7-tetramethyl-1,3,5,7-tetrahydroxylcyclosiloxane, 1,1,4,4-tetramethyl-1,4-diethoxydisylethylene, or 1,3,5-trimethyl-1,3,5-trimethyl-1,3,5-triethoxy-1,3,5-trisilacyclohexane may be incorporated for the purpose of improving the insulating property or the mechanical strength. Further, for the purpose of improving the hydrophobicity of the resin layer having an insulating property, methyltriethoxysilane, dimethyldiethoxysilane, trimethylethoxysilane, or the like may be incorporated. These compounds may also be incorporated for the purpose of controlling the etching selectivity.

The resin composition containing a resin material may also contain a solvent other than the polar solvent (D), and examples thereof include n-hexane.

Further, the resin composition containing a resin material may contain, for example, phthalic acid, benzoic acid, or a derivative thereof for the purpose of improving the electrical characteristics.

Moreover, the resin composition containing a resin material may contain, for example, benzotriazole or a derivative thereof for the purpose of inhibiting the corrosion of copper.

The pH of the resin composition containing a resin material is not particularly limited, and it is preferably from 2.0 to 12.0.

When the acid (C-1) is used as the additive (C), it is preferred to mix a mixture of the acid (C-1) and the compound (A) with the crosslinking agent (B). In other words, it is preferred to mix the compound (A) and the acid (C-1) in advance before mixing the compound (A) and the crosslinking agent (B). By this, when the compound (A) and the crosslinking agent (B) are mixed, the resin composition containing a resin material can be suitably prevented from being turbid and gelled (gelation may lead to an increase in the time required for making the resin composition transparent and is thus not preferred).

When the base (C-2) is used as the additive (C), it is preferred to mix a mixture of the base (C-2) and the crosslinking agent (B) with the compound (A). In other words, it is preferred to mix the crosslinking agent (B) and the base (C-2) in advance before mixing the compound (A) and the crosslinking agent (B). By this, when the compound (A) and the crosslinking agent (B) are mixed, the resin composition containing a resin material can be suitably prevented from being turbid and gelled (gelation may lead to an increase in the time required for making the resin composition transparent and is thus not preferred).

Examples of a method of applying a resin material to at least one surface of the substrate include: vapor phase deposition methods, such as vapor deposition polymerization, CVD (chemical vapor deposition), and ALD (atomic layer deposition); and coating methods, such as dipping, spraying, spin coating, and bar coating. In the case of applying a resin material by a coating method, it is preferred to apply a resin composition containing the resin material. For example, it is preferred to employ a bar coating method for the formation of a film having a thickness of the micron level, or it is preferred to employ a spin coating method for the formation of a film having a thickness of the nano level (several nanometers to several hundred nanometers). The film thickness of the resin material may be adjusted as appropriate in accordance with the intended thickness of the resulting resin layer.

For example, a method of applying a resin material by spin coating is not particularly limited and, for example, a method of dropping a resin composition containing the resin material onto the surface of the first substrate while rotating the substrate using a spin coater, and subsequently increasing the rotation speed of the substrate to dry the substrate can be employed.

In the method of applying a resin material by spin coating, various conditions such as the rotation speed of the substrate, the dropping amount and the dropping time of the resin composition containing the resin material, and the rotation speed of the substrate during drying are not particularly limited, and may be adjusted as appropriate taking into consideration the thickness and the like of the resin material to be formed.

In order to remove excess resin material from the substrate to which the resin material has been applied, the substrate may be washed. Examples of a washing method include wet washing with a rinsing liquid such as a polar solvent, and plasma cleaning.

In the method of producing a resin layer-equipped semiconductor chip according to the disclosure, the laminated body preparation step may include the step of curing the resin material applied to one surface of the semiconductor substrate to form a resin layer. For example, the resin material is cured by heating or the like to form a resin layer. In this case, when the resin material contains a thermosetting compound, the resin material is cured by heating at a temperature equal to or higher than a curing temperature.

The resin material applied to one surface of the substrate is preferably cured by heating at from 100° C. to 450° C.

This temperature refers to the surface temperature of the resin material applied to the above-described surface.

By heating the resin material, the solvent in the resin composition containing the resin material is removed. In addition, the components in the resin material react with each other to yield a cured product, and a resin layer containing the cured product is formed.

From the standpoint of preventing damage of a device such as a semiconductor memory caused by heat, the above-described temperature is preferably from 150° C. to 450° C., more preferably from 180° C. to 400° C., still more preferably from 180° C. to 250° C., particularly preferably from 180° C. to 200° C.

The pressure at which the heating of the resin material applied to the surface is performed is not particularly limited, and it is preferably an absolute pressure of higher than 17 Pa but atmospheric pressure or lower.

The absolute pressure is more preferably from 1,000 Pa to atmospheric pressure, still more preferably from 5,000 Pa to atmospheric pressure, particularly preferably from 10,000 Pa to atmospheric pressure.

The heating of the resin material applied to the surface can be performed by an ordinary method using a furnace or a hot plate. As the furnace, for example, SPX-1120 manufactured by APPEX Corporation or VF-1000LP manufactured by Koyo Thermo Systems Co., Ltd. can be used.

The heating of the resin material applied to the surface may be performed in an air atmosphere or an inert gas (e.g., nitrogen gas, argon gas, or helium gas) atmosphere.

The heating time of the resin material applied to the surface is not particularly limited and it is, for example, 3 hours or shorter, preferably 1 hour or shorter. A lower limit of the heating time is also not particularly limited and may be, for example, 5 minutes.

For the purpose of shortening the curing time of the resin material applied to the surface, the resin material applied to the surface may be irradiated with an ultraviolet (UV) light. The ultraviolet light is preferably, for example, an ultraviolet light having a wavelength of from 170 nm to 230 nm, an excimer light having a wavelength of 222 nm, or an excimer light having a wavelength of 172 nm. It is preferred to perform the UV irradiation in an inert gas atmosphere.

Whether the resin material is cured or not can be verified by, for example, measuring the peak intensities of specific bonds and structures by FT-IR (Fourier transform infrared spectroscopy). Examples of the specific bonds and structures include those bonds and structures that are generated by the crosslinking reaction.

For example, when an amide bond, an imide bond, a siloxane bond, a tetrahydronaphthalene structure, an oxazole ring structure, or the like is formed, it can be judged that the resin material is cured, and this can be confirmed by measuring the peak intensity derived from the respective bonds, structures, and the like by FT-IR.

An amide bond can be confirmed by the presence of vibration peaks at about 1,650 cm⁻¹ and about 1,520 cm⁻¹

An imide bond can be confirmed by the presence of vibration peaks at about 1,770 cm⁻¹ and about 1,720 cm⁻¹.

A siloxane bond can be confirmed by the presence of a vibration peak between 1,000 cm⁻¹ and 1,080 cm⁻¹.

A tetrahydronaphthalene structure can be confirmed by the presence of a vibration peak at 1,500 cm⁻¹.

An oxazole ring structure can be confirmed by the presence of vibration peaks at about 1,625 cm⁻¹ and about 1,460 cm⁻¹.

The resin layer formed by curing the resin material preferably has a siloxane bond and at least one bond selected from the group consisting of an ester bond, an ether bond, an amide bond, and an imide bond, more preferably has a siloxane bond and an imide bond.

In the resin layer formed by curing the resin material, the sodium content and the potassium content are each preferably 10 ppb by mass or less on an element basis. When the sodium content and the potassium content are each 10 ppb by mass or less on an element basis, problems in the electrical characteristics of a semiconductor device, such as malfunction of a transistor, can be inhibited.

The amount of silicon on each surface of the resin layer is independently preferably 20% by atom or less, more preferably 15% by atom or less, still more preferably 10% by atom or less.

The amount of silicon on each surface of the resin layer can be evaluated by measuring the atomic ratio using an X-ray photoelectron spectrometer (XPS). Specifically, using AXIS-NOVA (manufactured by Kratos Analytical Ltd.) that is an XPS, the atomic ratio can be measured from the peak intensities of a narrow spectrum, taking a total amount of elements detected in a wide spectrum as 100%.

The resin layer has a thickness of preferably from 0.001 μm to 8.0 μm, more preferably from 0.01 μm to 6.0 μm, still more preferably from 0.03 μm to 5.0 μm. By controlling the thickness of the resin layer to be 0.001 μm or more, the bonding strength of the resin layer with an inorganic material layer, other layer, and the like can be improved. By controlling the thickness of the resin layer to be 8.0 μm or less, a variation in the thickness of the resin layer can be inhibited when the resin layer is formed on a substrate having a large surface area.

When an electrode is arranged on a part of the surface of the resin layer, from the standpoint of improving the bonding strength of the resin layer with an inorganic material layer, other layer, and the like and inhibiting a variation in the thickness of the resin layer, the thickness of the resin layer is preferably from 0.01 μm to 8.0 μm, more preferably from 0.03 μm to 6.0 μm, still more preferably from 0.05 μm to 5.0 μm.

When an electrode is not arranged on the surface of the resin layer, from the standpoint of improving the bonding strength of the resin layer with an inorganic material layer, other layer, and the like and inhibiting a variation in the thickness of the resin layer, the thickness of the resin layer is preferably from 0.001 μm to less than 1.0 μm, more preferably from 0.01 μm to 0.8 μm, still more preferably from 0.03 μm to 0.6 μm.

From the standpoint of improving the bonding strength between the resin layer and other semiconductor chip or the like to be bonded, the resin layer preferably has a functional group capable of forming a chemical bond on the surface of the resin layer, more preferably has at least one functional group selected from the group consisting of a silanol group (Si—OH group), an amino group, an epoxy group, a hydroxy group, and an unsaturated bond-containing functional group. From the standpoint of heat resistance, the resin layer still more preferably has a silanol group on its surface. These functional groups may be formed by a surface treatment after the formation of the resin layer, or may be formed by a silane coupling agent treatment or the like. Alternatively, a compound containing these functional groups may be incorporated into the resin composition.

Examples of the unsaturated bond-containing functional group include a vinyl group, an allyl group, an acryl group, a methacryl group, and a styryl group.

The resin layer is preferably a resin layer having, on its surface, at least one functional group selected from the group consisting of a silanol group, an amino group, an epoxy group, a hydroxy group, and an unsaturated bond-containing functional group, or a resin layer formed of a resin material (hereinafter, may be referred to as “specific resin material”) that contains a siloxane bond and at least one bond selected from the group consisting of an ester bond, an ether bond, an amide bond, and an imide bond.

Whether or not the resin layer has a Si—OH group on its surface can be evaluated by a surface analysis of the resin layer based on time-of-flight secondary ion mass spectrometry (TOF-SIMS). Specifically, whether or not the resin layer has a Si—OH group on its surface can be evaluated based on the presence or absence of a peak at a mass-to-charge ratio (m/Z) of 45, using PHI nanoTOF II (manufactured by ULVAC-PHI, Inc.) that is a TOF-SIMS device.

After the formation of the resin layer, the resin layer may be flattened. Examples of a flattening method include fly cutting and chemical mechanical polishing (CMP). These flattening methods may be employed singly, or in combination of two or more thereof.

After the formation of the resin layer, the resin layer may be washed as well. Examples of a washing method include wet washing with a rinsing liquid, and dry washing with plasma or the like. Examples of the wet washing include ultrasonic washing with pure water, and spin washing with a solvent such as NMP.

### (Electrode)

The laminated body may include an electrode exposed from a part of the resin layer, or may include an electrode exposed to parts of both surfaces. A through-hole penetrating through the laminated body from one side to the other side may be formed, and an electrode (through electrode) penetrating the through-hole may then be arranged.

The material of the electrode is not particularly limited, and examples thereof include conventionally known electrode materials, specifically copper, solder, tin, gold, silver, aluminum, indium, cobalt, and tungsten.

A method of arranging an electrode on the laminated body is not particularly limited, and any conventionally known method may be employed.

For example, the electrode may be formed on a surface to be coated with the resin material before the formation of the resin layer of the laminated body, or the electrode may be formed on a surface on which the resin layer has been formed.

Alternatively, the electrode may be formed on a surface on which an inorganic material layer is to be formed before the formation of the inorganic material layer on the surface of the semiconductor substrate that is opposite to the surface of the resin layer side, or the electrode may be formed on a surface on which the inorganic material layer has been formed.

The electrode may be formed in a convex shape on a surface of a substrate, or may be formed in the state of penetrating through the substrate, or in the state of being embedded in the substrate.

When forming a resin layer on one surface of a substrate and an inorganic material layer on the other surface, the order of forming the resin layer and the inorganic material layer is not particularly limited. For example, the resin layer may be formed on one surface of the substrate and then the inorganic material layer may be formed on the other surface of the substrate, or conversely, the inorganic material layer may be formed and then the resin layer may be formed.

When the electrode is formed before the formation of the resin layer or the inorganic material layer, the resin layer or the inorganic material layer on the electrode is removed after the formation thereof, whereby a configuration in which the electrode is provided on a part of the surface of the resin layer or a part of the surface of the inorganic material layer is obtained. Examples of a method of removing the resin layer or the inorganic material layer on the electrode include fly cutting, chemical mechanical polishing (CMP), and plasma dry etching. These removal methods may be employed singly, or in combination of two or more thereof. For example, a surface planer (DFS8910, manufactured by DISCO Corporation) can be used for fly cutting. When CMP is employed, as a slurry, for example, a slurry containing silica or alumina, which is generally used for polishing a resin, or a slurry containing hydrogen peroxide and silica, which is used for polishing a metal, may be used. When plasma dry etching is employed, fluorocarbon plasma, oxygen plasma, or the like may be used.

When the resin layer or the inorganic material layer on the electrode is removed to expose the electrode, a reduction treatment of oxides on the surface of the electrode may be performed if necessary. Examples of a reduction treatment method include a method of heating the substrate in an acid atmosphere of formic acid or the like at from 100° C. to 300° C., and a method of heating the substrate in a hydrogen atmosphere. These treatments may be performed simultaneously with the below-described heating step.

When the electrode is formed after the formation of the resin layer or the inorganic material layer, for example, a hole in which the electrode is to be formed may be formed by a known method on the surface of the substrate on which the resin layer or the inorganic material layer is formed, and the electrode may be formed in the thus formed hole. Examples of a method of forming the hole include dry etching with a gas, and laser ablation.

Examples of a method of forming the electrode include electrolytic plating, electroless plating, sputtering, and ink-jetting.

When the resin material is photosensitive, the hole in which the electrode is to be formed may be formed by photolithography in the resin material applied to at least one surface of the substrate. The electrode may be formed in the thus formed hole after the resin material is cured to form the resin layer.

### [Attachment Step]

The method of producing a resin layer-equipped semiconductor chip according to the disclosure includes the attachment step of attaching the laminated body 20 to the dicing tape 42 such that the resin layer 23 is exposed (FIG. 2(A)).

As the dicing tape 42, for example, a dicing tape in which an adhesive layer whose adhesive strength decreases when irradiated with an ultraviolet (UV) light is provided on one surface of a resin film can be used. From the standpoint of ease of handling, as illustrated in FIG. 2, the dicing tape is preferably immobilized on one surface of a frame 44 which has an opening larger than the laminated body 20.

### [Protective Layer Formation Step]

The method of producing a resin layer-equipped semiconductor chip according to the disclosure includes the protective layer formation step of forming the protective layer 33 on the resin layer 23 of the laminated body 20.

The protective layer 33 is not particularly limited as long as it protects the resin layer 23 in the dicing step, and can be selectively removed after the dicing step. The protective layer 33 is formed of, for example, a water-soluble resin, or a photoresist that can be washed with a developer containing TMAH (tetramethylammonium hydroxide) or an organic solvent such as NMP (N-methyl-2-pyrrolidone). As the water-soluble resin, HOGOMAX manufactured by DISCO Corporation can be used.

A method of forming the protective layer 33 on the resin layer 23 is not particularly limited, and examples thereof include a method of spin-coating a composition for the formation of the protective layer 33 onto the resin layer 23 and subsequently curing the composition by drying, heating, or the like.

The protective layer 33 has a thickness in a range of, for example, from 0.1 μm to 1 mm.

### [Groove Formation Step]

The method of producing a resin layer-equipped semiconductor chip according to the disclosure includes the groove formation step of forming the grooves 34 penetrating through the protective layer 33 and the resin layer 23 by laser ablation (FIG. 2(B)).

For example, laser light L is irradiated from the protective layer 33 side to form the grooves (openings) 34 penetrating through the protective layer 33 and the resin layer 23. In other words, parts of the protective layer 33 and the resin layer 23 are heated and vaporized by a laser ablation process, as a result of which the grooves 34 are formed and parts of the semiconductor substrate 21 are exposed. The grooves 34 can be formed in a prescribed pattern in accordance with the size and the shape of the resin layer-equipped semiconductor chip to be produced.

### [Dicing Step]

The method of producing a resin layer-equipped semiconductor chip according to the disclosure includes the dicing step of dicing the semiconductor substrate 21 through the grooves 34 to singulate the semiconductor substrate 21 (FIG. 2(D)).

As a dicing method, a dicing method using a laser is preferred, and specific examples of the dicing method include plasma dicing, laser full-cut dicing, and stealth dicing.

Plasma dicing is a method of forming a mask on a semiconductor substrate and performing dry-etching through the mask under vacuum to singulate a silicon substrate. For example, the Bosch process can be applied. Specifically, by repeating the following three steps: isotropic etching of Si; deposition of a protective film; and anisotropic etching of Si (removal of the protective film on the bottom surface), those parts of the silicon substrate 21 that are exposed from the grooves 34 can be dug deeper in the depth direction. For example, SF₆ is used for etching, and C₄F₈ is used for the protective film. For example, after the formation of the grooves 34 on the protective layer 33 and the resin layer 23 by a laser ablation process, the laminated body is placed in a treatment chamber of a plasma treatment device (not illustrated) with the laminated body being attached to the dicing tape 42, and plasma dicing is performed by repeating the above-described three steps from the side of the protective layer 33A. The remaining parts of the protective layer 33 and the resin layer 23 function as a mask at the time of plasma-etching the exposed parts of the semiconductor substrate 21 in the plasma dicing step. Since the protective layer 33A is formed on the resin layer 23A, the resin layer 23A can be prevented from being damaged by plasma etching.

Laser full-cut dicing is a method of irradiating the surface of a semiconductor substrate with a laser once or multiple times to fully cut the semiconductor substrate to the dicing tape. Laser full-cut dicing gives processing marks that are thinner than those made by blade dicing, and can inhibit the generation of burrs.

Stealth dicing is a method of focusing a laser, which has a wavelength transparent to a semiconductor substrate to be processed, inside the semiconductor substrate to form a modified layer, and subsequently expanding (pulling) and thereby singulating the semiconductor substrate.

In the silicon substrate 21, since the protective layer 33A is formed on the resin layer 23A, damage to the resin layer 23A caused by dicing can be inhibited in any of the above-described dicing methods using a laser.

### [Protective Layer Removal Step]

The method of producing a resin layer-equipped semiconductor chip according to the disclosure includes the protective layer removal step of removing the protective layer 33A after the dicing step (FIG. 2(E)).

A method of removing the protective layer 33A is not particularly limited as long as it is a method that removes the protective layer 33A and allows the resin layer 23A to remain on the silicon substrate 21A without being removed. A means for removing the protective layer 33A may be selected in accordance with the materials and the like of the protective layer 33A and the resin layer 23A and, for example, when the protective layer 33A is formed of a water-soluble resin, only the protective layer 33A can be simply removed by washing with water.

When the protective layer 33A is not formed of a water-soluble resin, it is removed by ashing, chemical cleaning, or the like.

From the standpoint of removing particles and the like, the method of producing a resin layer-equipped semiconductor chip according to the disclosure may also include the step of washing the resin layer-equipped semiconductor chip 20A after the dicing step.

A washing method is not particularly limited, and examples include: wet washing with a solvent such as an alkaline washing solution, an acidic washing solution, a hydrofluoric acid-containing washing solution, or a permanganic acid-containing solution (desmear solution); wet washing with pure water or the like; and dry washing with UV ozone, plasma, or the like.

This washing step may be performed together with the protective layer removal step.

### <Method of Producing Substrate Laminated Body>

A resin layer-equipped semiconductor chip that is produced by the method of producing a resin layer-equipped semiconductor chip according to the disclosure can be stacked and bonded onto other semiconductor substrate or other semiconductor chip to produce a substrate laminated body.

In other words, the method of producing a substrate laminated body according to the disclosure includes:
the stacking step of peeling off a semiconductor chip, which is produced by the method of producing a semiconductor chip according to the disclosure, from a dicing tape, and stacking the thus obtained resin layer-equipped semiconductor chip on other semiconductor substrate or other semiconductor chip such that the resin layer of the resin layer-equipped semiconductor chip is in contact with the other semiconductor substrate or the other semiconductor chip; and
the heating step of heating and thereby bonding the thus stacked resin layer-equipped semiconductor chip and the other semiconductor substrate or the other semiconductor chip.

The method of producing a substrate laminated body according to the disclosure may also include, after the stacking step but before the heating step, other steps such as the temporary fixation step of temporarily fixing the stacked resin layer-equipped semiconductor chip, and the cleaning step.

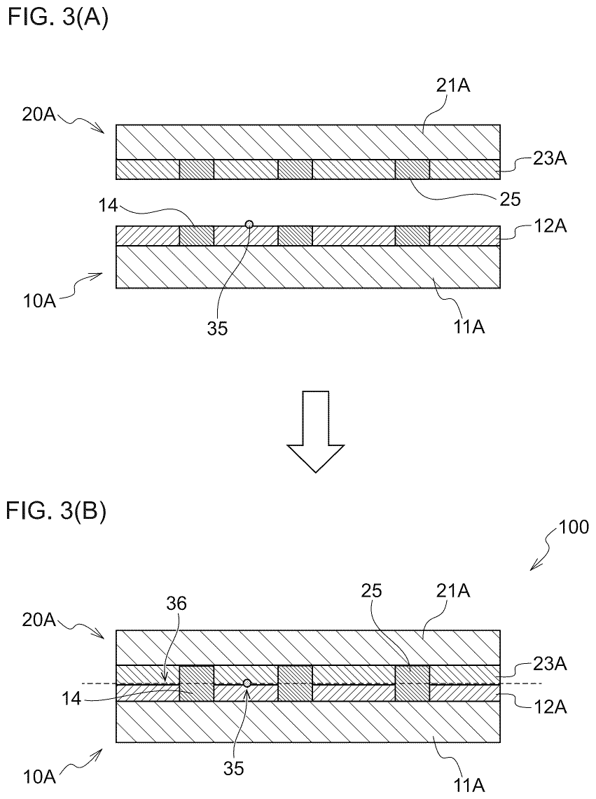

FIGS. 3(A) and 3(B) schematically illustrate the stacking step and the heating step that are included in one example of the method of producing a substrate laminated body according to the disclosure.

### [Stacking Step]

The method of producing a substrate laminated body according to the disclosure includes the stacking step of peeling off the resin layer-equipped semiconductor chip 20A produced by the above-described method of producing a resin layer-equipped semiconductor chip according to the disclosure from the dicing tape 42, and stacking the resin layer-equipped semiconductor chip 20A on other semiconductor substrate or other semiconductor chip 10A such that the resin layer 23A of the resin layer-equipped semiconductor chip 20A is in contact with the other semiconductor substrate or the other semiconductor chip 10A (FIG. 3(A)).

The resin layer-equipped semiconductor chip 20A (hereinafter, may be referred to as “semiconductor chip 20A”) produced by the method of producing a resin layer-equipped semiconductor chip according to the disclosure is picked up from the dicing tape 42 by a handling device (not illustrated), and stacked such that the electrodes 25 exposed from the resin layer 23A of the semiconductor chip 20A come into contact with the corresponding electrodes 14 of the other semiconductor chip 10A. In FIGS. 3(A) and 3(B), the other semiconductor chip 10A on which the semiconductor chip 20A is stacked is configured such that an inorganic material layer 12A formed of SiO₂ is stacked on a silicon substrate 11A, and the electrodes 14 are exposed from the inorganic material layer 12A.

When the inorganic material layer and the resin layer are brought into contact in the stacking step, the resin layer before the contact preferably has a curing rate of from 70% to 100%. This allows the semiconductor chips 10A and 20A to be firmly bonded in the below-described temporary fixation step and heating step, and tends to make displacement in bonding (misalignment) less likely to occur.

The curing rate of the resin layer is more preferably 80% or higher, still more preferably 85% or higher, particularly preferably 90% or higher, further preferably 93% or higher. Meanwhile, the curing rate of the resin layer may be 100%, 99% or less, 95% or less, or 90% or less.

The curing rate of the resin layer may be that of before the resin layer is brought into contact with other layer (e.g., other inorganic material layer).

The curing rate of a resin layer that contains at least one selected from the group consisting of an amide bond, an imide bond, a siloxane bond, a tetrahydronaphthalene structure, an oxazole ring structure, an ester bond, and an ether bond is more preferably 80% or higher, still more preferably 85% or higher, particularly preferably 90% or higher, further preferably 93% or higher. The curing rate of a resin layer that contains a siloxane bond and at least one selected from the group consisting of an ester bond, an ether bond, an amide bond, and an imide bond is more preferably 80% or higher, still more preferably 85% or higher, particularly preferably 90% or higher, further preferably 93% or higher.

The curing rate of the resin layer obtained by curing the resin material may be confirmed by, for example, measuring the peak intensities of specific bonds and structures (a total peak intensity in the case of having multiple peaks as in imide, amide, and the like) by FT-IR (Fourier transform infrared spectroscopy) for the resin material prior to being applied to the substrate, the resin layer prior to being brought into contact with the inorganic material layer in the stacking step, and the resin layer after the heating step, and determining the peak intensity increase rate or decrease rate. It is noted here that, when there are band-like peaks that are difficult to separate as in the case of a siloxane bond or the like, a maximum peak intensity may be used.

Specifically, when a specific bond and structure is generated by a curing reaction, the peak intensity increase rate may be calculated by the following equation, and the thus calculated value may be adopted as the curing rate of the resin layer.

Peak intensity increase rate (Curing rate of resin layer)=[(Peak intensity of specific bond and structure of resin layer prior to being brought into contact with inorganic material layer in stacking step)/(Peak intensity of specific bond and structure of resin layer after being heated at 300° C. for 1 hour in heating step)]×100

It is noted here that background signals may be removed by any ordinary method. If necessary, the FT-IR measurement can be performed by a transmission method or a reflection method.

In the above-described peak intensity increase rate, when there are plural bonds and structures that cause an increase in the peak intensity, “peak intensity” may read “sum of plural peak intensities”.

Before the resin layer and the inorganic material layer are brought into contact in the stacking step, the resin layer has a composite elastic modulus at 23° C. of preferably from 0.1 GPa to 20 GPa, more preferably from 0.1 GPa to 10 GPa. By this, voids that are formed when the resin layer and the inorganic material layer are brought into contact in the stacking step are absorbed into the resin layer in the heating step, so that the generation of voids tends to be inhibited.

From the standpoint of preferably inhibiting the generation of voids, the composite elastic modulus of the resin layer at 23° C. is preferably 8 GPa or less, more preferably 6 GPa or less. Meanwhile, from the standpoint of preferably inhibiting the misalignment, the composite elastic modulus of the resin layer at 23° C. is preferably 0.1 GPa or more, more preferably 1 GPa or more.

A preferred range of the composite elastic modulus of the resin layer at 23° C. is the same as that of the composite elastic modulus of the resin layer at 23° C. The composite elastic modulus of the resin layer at 23° C. may be the composite elastic modulus of the resin layer at 23° C. prior to being brought into contact with other layer (e.g., other inorganic material layer).

The composite elastic modulus of the resin layer at 23° C. can be measured by the following method.

A resin composition containing the resin material is prepared, spin-coated on a silicon substrate, and then heated at 400° C. for 10 minutes to prepare a measurement sample. For the thus prepared measurement sample, the unloading-displacement curve at 23° C. is measured at a test depth of 20 nm using a nano-indenter (product name: TI-950 TRIBO INDENTER, manufactured by Hysitron, Inc.; Berkovich-type indenter), and the composite elastic modulus at 23° C. is calculated from a maximum load and a maximum displacement in accordance with the calculation method described in the reference literature (Handbook of Micro/Nano Tribology (Second Edition), edited by Bharat Bhushan, CRC Press).

The composite elastic modulus is defined by the following Equation (1). In Equation (1), Eᵣ represents the composite elastic modulus; Eᵢ represents the Young's modulus of the indenter, which is 1,140 GPa; νᵢ represents the Poisson's ratio of the indenter, which is 0.07; and Eₛ and νₛ represent the Young's modulus and the Poisson's ratio of the sample, respectively.

$$\frac{1}{{E}_{r}} = \frac{1 - {v}_{i}^{2}}{{E}_{i}} + \frac{1 - {v}_{s}^{2}}{{E}_{s}} \qquad ( 1 )$$

Before the inorganic material layer and the resin layer are brought into contact with each other in the stacking step, the inorganic material layer has a surface roughness (Ra) of preferably from 0.01 nm to 1.2 nm, more preferably from 0.1 nm to 1.0 nm. This makes it easy to perform the below-described temporary fixation of the inorganic material layer and the resin layer at a low temperature.

A preferred range of the surface roughness (Ra) of the resin layer is the same as that of the inorganic material layer.

The surface roughness (Ra) of each layer may be the surface roughness (Ra) measured before the layers are brought into contact with each other.

The surface roughness of each layer can be evaluated by morphological observation under a scanning probe microscope (SPM). Specifically, the surface roughness is determined by measuring a 3 μm×3 μm square area using SPA400 (manufactured by Hitachi High-Tech Corporation), which is an SPM, in the dynamic force microscope mode.

The method of producing a substrate laminated body according to the disclosure may also include the below-described steps before the above-described stacking step. The below-described steps are preferably performed after the laminated body preparation step but before the stacking step.

The method of producing a substrate laminated body according to the disclosure may include the step of performing a surface activation treatment on the resin layer 23A before the stacking step. By performing the surface activation treatment, the bonding strength between the inorganic material layer and the resin layer can be improved. Particularly, when electrodes are arranged on a bonding surface of the semiconductor chip 10A and the semiconductor chip 20A and bonded to each other, it is preferred to perform the surface activation treatment from the standpoint of facilitating the diffusion of metals such as copper contained in the electrodes to improve the bonding strength between the electrodes, as well as from the standpoint of lowering the heating temperature for the diffusion of metals.

The surface activation treatment may also be performed on the inorganic material layer 12A of the semiconductor chip 10A and, particularly, the surface activation treatment may be performed on the inorganic material layer before the inorganic material layer is brought into contact with other layer (e.g., the resin layer).

Specific examples of the surface activation treatment include a plasma treatment and a FAB (Fast Atom Bombardment) treatment.

### [Temporary Fixation Step]

The method of producing a substrate laminated body according to the disclosure may include the temporary fixation step of temporarily fixing the stacked semiconductor chip 10A and semiconductor chip 20A at a first temperature.

The temporary fixation of the semiconductor chip 10A and the semiconductor chip 20A is performed at a first temperature, for example, at a low temperature of room temperature (e.g., 23° C.) or higher but lower than 100° C. The temporary fixation is preferably performed at a low temperature of from room temperature to 50° C., more preferably at room temperature. Particularly, when the resin layer is formed of the above-described specific resin material, the temporary fixation can be performed even at room temperature.

When the semiconductor substrates 11A and 21A each include a silicon substrate, from the standpoint of ease of handling, inhibition of misalignment (bonding displacement), inhibition of inclusion of foreign substances, and the like in the heating step, the bonding interface of the semiconductor chip 10A and the semiconductor chip 20A in a temporarily fixed state has a surface energy of preferably 0.05 J/m² or more, more preferably 0.1 J/m² or more, still more preferably 0.15 J/m² or more.

The surface energy (bonding strength) of the bonding interface can be determined by a blade insertion test in accordance with the method described in a non-patent document “M.P. Maszara, G. Goetz, A. Cavigila, and J. B. Mckitterick, Journal of Applied Physics, 64 (1988) 4943-4950”. A blade having a thickness of from 0.1 mm to 0.3 mm is inserted to the bonding interface of the temporarily fixed semiconductor chips, and the distance of detachment of the semiconductor chips from the tip of the blade is measured using an infrared light source and an infrared camera. Thereafter, the surface energy may be determined based on the following equation:

$$γ = 3 \times 1 {0}^{9} \times {t}_{b}^{2} \times {E}^{2} \times {t}^{6} / ( 32 \times {L}^{4} \times E \times {t}^{3} )$$

In this equation, γ represents the surface energy (J/m²); tb represents the blade thickness (m); E represents the Young's modulus (GPa) of the silicon substrate in the semiconductor substrates; t represents the thickness (m) of the semiconductor substrates; and L represents the detachment distance (m) of the semiconductor chips from the tip of the blade.

### [Heating Step]

The method of producing a substrate laminated body according to the disclosure includes the heating step of heating and thereby bonding the stacked resin layer-equipped semiconductor chip 20A and other semiconductor substrate or other semiconductor chip 10A (FIG. 3(B)).

After the stacking step, the above-described temporary fixation step is performed if necessary, and heating is subsequently performed, whereby the semiconductor chips 10A and 20A can be bonded to each other, and a substrate laminated body 100 can be produced.

In the heating step, the heating is performed at a second temperature higher than the first temperature in the temporary fixation step, for example, at 100° C. or higher. By the heating step, the substrate laminated body 100 in which the semiconductor chips 10A and 20A are bonded via the inorganic material layer 12A and the resin layer 23A is obtained.

The pressure at which the semiconductor chip 10A and the semiconductor chip 20A are bonded is not particularly limited, and it is preferably an absolute pressure of higher than 10⁻⁴ Pa but atmospheric pressure or lower.

The absolute pressure is more preferably from 10⁻³ Pa to atmospheric pressure, still more preferably from 100 Pa to atmospheric pressure, particularly preferably from 1,000 Pa to atmospheric pressure.

The bonding of the semiconductor chip 10A and the semiconductor chip 20A may be performed in an air atmosphere or an inert gas (e.g., nitrogen gas, argon gas, or helium gas) atmosphere.

In the heating step, the semiconductor chip 10A and the semiconductor chip 20A that have been temporarily fixed are preferably heated at a temperature of from 100° C. to 450° C. with the inorganic material layer 12A and the resin layer 23A being in contact with each other.

This heating temperature refers to the surface temperature of the semiconductor chip 20A.

The heating temperature is preferably from 100° C. to 400° C., more preferably from 130° C. to 350° C., still more preferably from 150° C. to 300° C., yet still more preferably from 150° C. to 250° C., particularly preferably from 150° C. to 200° C.

When each electrode 14 and each electrode 25, which are provided on the inorganic material layer 12A side and the resin layer 23A side in the stacking step, respectively, are arranged such that these electrodes are in contact with each other, the above-described temperature is preferably 130° C. or higher, more preferably 150° C. or higher, still more preferably 200° C. or higher. This allows diffusion of the components (e.g., copper) that are contained in the electrode arranged on the inorganic material layer side and the electrode arranged on the resin layer side, so that the bonding strength between these electrodes tends to be improved.

The heating in the heating step can be performed by an ordinary method using a furnace or a hot plate.

Further, the heating in the heating step may be performed in an air atmosphere or an inert gas (e.g., nitrogen gas, argon gas, or helium gas) atmosphere.

The heating time in the heating step is not particularly limited and it is, for example, 3 hours or shorter, preferably 1 hour or shorter. A lower limit of the heating time is also not particularly limited and may be, for example, 5 minutes.

In the heating step, from the standpoint of improving the bonding strength between the semiconductor chip 10A and the semiconductor chip 20A, the semiconductor chip 10A and the semiconductor chip 20A may be pressurized with the inorganic material layer and the resin layer being in contact with each other. This pressurization may be performed simultaneously with the heating.

The pressure to be applied at the time of pressurizing the temporarily fixed semiconductor chips 10A and 20A is not particularly limited, and it is preferably from 0.1 MPa to 10 MPa, more preferably from 0.1 MPa to 5 MPa. As a pressurizing device, for example, TEST MINI PRESS manufactured by Toyo Seiki Seisaku-sho, Ltd. can be used.

For example, when the contact surfaces of the two semiconductor chips to be stacked are each formed of an inorganic material layer of SiO₂ or the like, and a foreign matter such as particles exists on the bonding surface, defective bonding is likely to occur due to voids generated by the foreign matter.

On the other hand, when the semiconductor chip 20A is produced by the method of producing a resin layer-equipped semiconductor chip according to the disclosure, irregularities (vertical streaks) on the side surface (cut surface) of the silicon substrate 21A are reduced, and the generation of particles during handling is inhibited. Further, as illustrated in FIGS. 3(A) and 3(B), even if a foreign matter 35 such as a particle exists on a bonding surface 36 of the semiconductor chips 10A and 20A, the resin layer 23A of the semiconductor chip 20A conforms to the foreign matter 35, so that defective bonding due to a void generated by the foreign matter 35 is unlikely to occur.

When the semiconductor chips are bonded to each other via resin layers, misalignment is likely to occur due to a resin flow at the time of bonding, resulting in defective bonding between the electrodes; however, by performing the bonding between the inorganic material layer 12A and the resin layer 23A, misalignment can be inhibited as well.

In the method of producing a substrate laminated body according to the disclosure, after the heating step, if necessary, a thinning process (back grinding or back-surface polishing) may be performed on the surface of the resulting substrate laminated body.

Further, the method of producing a substrate laminated body according to the disclosure may include, after the heating step, the step of arranging a through-hole in the thickness direction of the semiconductor chip 10A and the semiconductor chip 20A and then forming an electrode penetrating through the semiconductor chip 10A and the semiconductor chip 20A in the through-hole. When no electrode is formed on the substrate laminated body obtained in the heating step, it is preferred that, by performing this step of forming an electrode, an electrode penetrating through the semiconductor chip 10A and the semiconductor chip 20A is formed in the through-hole.

For example, a through-hole penetrating through the semiconductor chip 10A and the semiconductor chip 20A may be formed by any known method, and an electrode may be formed in the thus formed hole. Examples of a method of forming the hole include dry etching with a gas, and laser ablation.

Examples of a method of forming the electrode penetrating through the semiconductor chip 10A and the semiconductor chip 20A include electrolytic plating, electroless plating, sputtering, and ink-jetting.

The material of the electrode penetrating through the semiconductor chip 10A and the semiconductor chip 20A is not particularly limited, and examples thereof include conventionally known electrode materials, specifically copper, solder, tin, gold, silver, aluminum, indium, cobalt, and tungsten.

In the method of producing a substrate laminated body according to the disclosure, after the temporary fixation step of the semiconductor chips 10A and 20A but before the heating step, the step of further stacking and temporarily fixing other semiconductor chip (not illustrated) on the semiconductor chip 20A may be repeatedly performed to stack semiconductor chips.

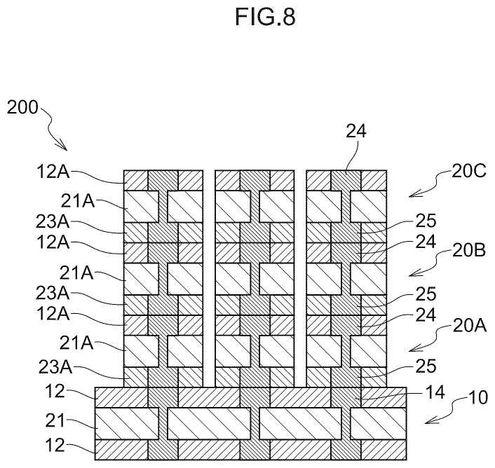

Preferably, the resin layer is formed of a specific resin material and, for example, a substrate laminated body 200, in which resin layer-equipped semiconductor chips 20A, 20B, and 20C produced by the method of producing a resin layer-equipped semiconductor chip according to the disclosure are each bonded between the inorganic material layer 12 or 12A and the resin layer 23A and stacked in three levels on the semiconductor substrate 10 as illustrated in FIG. 8, can be produced. The substrate laminated body 200, in which not only the generation of particles and the contamination of bonding surfaces during handling of the resin layer-equipped semiconductor chips 20A, 20B, and 20C are inhibited but also the resin layer-equipped semiconductor chips 20A, 20B, and 20C are bonded in multiple levels, can be produced by a single heating step. Therefore, not only damage to each laminated body caused by heating can be inhibited, but also the production cost associated with the heating step can be kept low.

The resin layer-equipped semiconductor chips 20A, 20B, and 20C that are bonded to each other at each level may have the same configuration or different configurations. Further, the number of the resin layer-equipped semiconductor chips to be stacked is not particularly limited, and may be set as required.

### EXAMPLES

An Example of the method of producing a resin layer-equipped semiconductor chip according to the disclosure will now be described. It is noted here that below-described Example is merely one example of the conditions adopted for verifying the feasibility and the effects of the method of producing a resin layer-equipped semiconductor chip according to the disclosure. Therefore, the method of producing a resin layer-equipped semiconductor chip according to the disclosure is not limited to the below-described Example.

### Example 1

### <Production of Resin Layer-Equipped Silicon Substrate>

A 1 μm-thick resin layer was formed on one surface of a silicon substrate having a diameter of 200 mm and a thickness of 200 μm by the below-described method to produce a resin layer-equipped silicon substrate.

### <Preparation of Composition for Formation of Resin Layer>

A composition for the formation of the resin layer was prepared. The details are as follows.

As a silane compound (A) and a crosslinking agent (B), 3-aminopropyldiethoxymethylsilane (3APDES) and symmetric oxydiphthalic acid ethyl half-ester (ODPAehe) were prepared, respectively.

ODPAehe was obtained by adding symmetric oxydiphthalic anhydride (ODPA) to ethanol, and heating the resultant to reflux for 4 hours until a transparent liquid was obtained. Then, it was confirmed by proton NMR that an ester group was formed in the thus produced ODPAehe. Ethanol was removed using an evaporator to produce a liquid concentrated to a half-ester compound concentration of 70% to 75%, and this liquid was used as the crosslinking agent (B).

After adding dropwise 25 g of the silane compound (A) to 25 g of water and dissolving the silane compound (A) to 50% by mass, the resultant was left to stand overnight at room temperature. Subsequently, it was confirmed by a proton NMR spectrum that ethoxysilane was hydrolyzed. Further, the silane compound (A) and then the crosslinking agent (B) were added such that a molar ratio (A)/(B) of 1/1 was attained, and the resultant was stirred overnight at room temperature, whereby a composition for the formation of the resin layer was prepared.

### <Formation of Resin Layer>

As a substrate to which the thus prepared composition was to be applied, a silicon substrate (silicon wafer) having a diameter of 8 inches was prepared. This silicon wafer was treated with UV (ultraviolet) ozone for 5 minutes and then placed on a spin coater, and about 5 mL of the concentration-adjusted composition was applied dropwise onto the silicon wafer. After the silicon wafer was maintained for 13 seconds, the silicon wafer was dried by being rotated at 2,000 rpm (rpm is the unit of rotation speed) for 1 second, at 600 rpm for 30 seconds, and then at 2,000 rpm for 10 seconds. This silicon wafer was left to stand overnight and then heated in an inert oven at 200° C. for 1 hour, whereby a cured 1 μm-thick resin layer was obtained.

### <Formation of Protective Layer>

On the thus obtained resin layer, HOGOMAX (manufactured by DISCO Corporation) was spin-coated (1,500 rpm) as a composition for the formation of a protective layer and then dried, whereby a 5 μm-thick protective layer was formed.

### <Groove Formation>

A dicing tape (D-628, manufactured by LINTEC Corporation) was attached to the surface of the silicon substrate on the side opposite to the surface in contact with the resin layer, and a laser was subsequently irradiated from the protective layer side, whereby grooves penetrating the protective layer and the resin layer and having a width of about 55 μm were formed at 7.3-mm intervals both vertically and horizontally.

### <Plasma Etching>

Using a plasma etching device, plasma etching was performed with SF₆ gas and C₄F₈ gas from the protective layer side, and parts of the silicon substrate were thereby plasma-etched through the grooves. As a result, the silicon substrate was divided into chips.

### <Removal of Protective Layer>

After the plasma etching, the protective layer was removed by washing with water.

Thereafter, the surface of the dicing tape on the side opposite to the surface attached to the silicon substrate was irradiated with UV light to detach a resin layer-equipped semiconductor chip from the dicing tape.

Through the above-described steps, a resin layer-equipped semiconductor chip 1 in which the resin layer was arranged on the singulated silicon substrate was produced.

### Comparative Example 1

A 1 μm-thick SiO₂ layer was formed on one surface of a silicon substrate having a diameter of 200 mm and a thickness of 200 μm by a CVD (chemical vapor deposition) method using TEOS (tetraethoxysilane) as a raw material to produce a SiO₂ layer-equipped silicon substrate.

### <Formation of Protective Layer>

On the thus obtained SiO₂ layer, HOGOMAX (manufactured by DISCO Corporation) was spin-coated as a composition for the formation of a protective layer and then dried, whereby a 5 μm-thick protective layer was formed.

### <Groove Formation>

A dicing tape (D-628, manufactured by LINTEC Corporation) was attached to the surface of the silicon substrate on the side opposite to the surface in contact with the SiO₂ layer, and a laser was subsequently irradiated from the protective layer side, whereby grooves penetrating the protective layer and the SiO₂ layer and having a width of about 55 μm were formed at 7.3-mm intervals both vertically and horizontally.

### <Plasma Etching>

Using a plasma etching device, plasma etching was performed from the protective layer side under the same conditions as in Example 1, and parts of the silicon substrate were thereby plasma-etched through the grooves. As a result, the silicon substrate was divided into chips.

### <Removal of Protective Layer>

After the plasma etching, the protective layer was removed by washing with water.

Thereafter, the surface of the dicing tape on the side opposite to the surface attached to the silicon substrate was irradiated with UV light to detach a semiconductor chip from the dicing tape.

Through the above-described steps, a SiO₂ layer-equipped semiconductor chip 2 in which the SiO₂ layer was arranged on the silicon substrate was produced.

### [Evaluation]

For each of the semiconductor chips produced in Example 1 and Comparative Example 1, an end portion of the silicon substrate was observed under an optical microscope at a magnification of ×1,500 from the surface of the resin layer or the SiO₂ layer, i.e., such that the surface cut by plasma etching was viewed from the above.

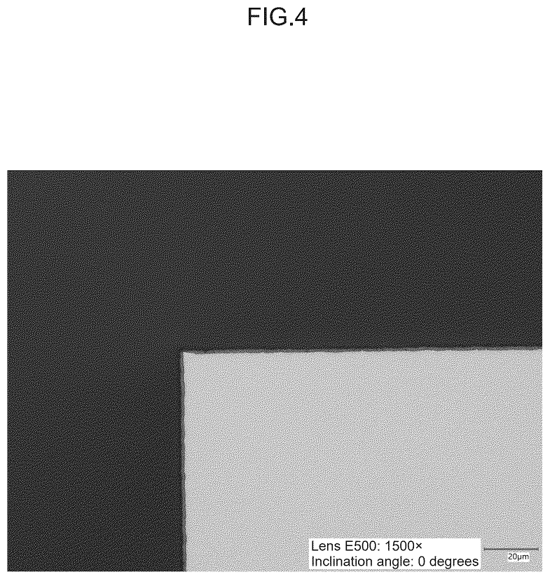

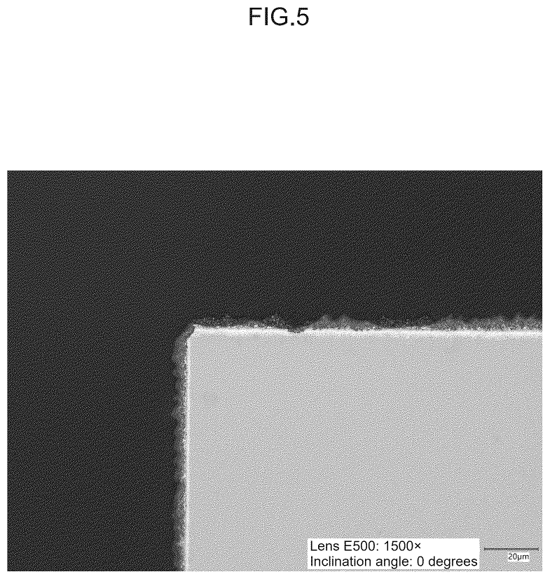

FIG. 4 is an optical micrograph obtained by observing an end portion of the silicon substrate in the resin layer-equipped semiconductor chip 1 produced in Example 1 from the resin layer surface, and FIG. 5 is an optical micrograph obtained by observing an end portion of the silicon substrate in the SiO₂ layer-equipped semiconductor chip 2 produced in Comparative Example 1 from the SiO₂ layer surface. It is seen that, as compared to the side surface of the silicon substrate in the SiO₂ layer-equipped semiconductor chip 2 produced in Comparative Example 1, the side surface of the silicon substrate in the resin layer-equipped semiconductor chip 1 has a smoother shape with reduced irregularities.

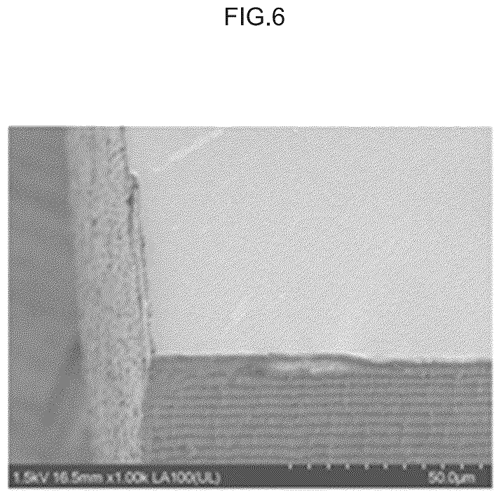

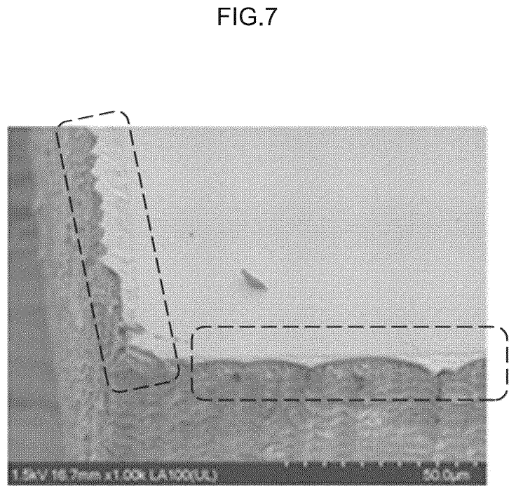

FIG. 6 is an SEM image obtained by observing the end portion of the silicon substrate in the resin layer-equipped semiconductor chip 1 produced in Example 1 from diagonally above, and FIG. 7 is an SEM image obtained by observing the end portion of the silicon substrate in the SiO₂ layer-equipped semiconductor chip 2 produced in Comparative Example 1 from diagonally above. In Example 1, within the visual field of the SEM image, only one protrusion (bulge) of 1 to 2 μm in height is observed in the end portion, and the end portion has a smooth shape with reduced formation of irregularities. In Comparative Example 1, within the visual field of the SEM image, about 10 protrusions (bulges) of 5 to 10 μm in height are observed in the end portion (parts enclosed in dashed lines), and it is thus seen that the formation of irregularities in the end portion was not inhibited.

The disclosure of Japanese Patent Application No. 2023-025618 filed on Feb. 21, 2023 is hereby incorporated by reference in its entirety.

All the documents, patent applications, and technical standards that are described in the present specification are hereby incorporated by reference to the same extent as if each individual document, patent application, or technical standard is concretely and individually described to be incorporated by reference.

### DESCRIPTION OF SYMBOLS

10: Semiconductor substrate
10A: Semiconductor chip
11A: Silicon substrate
12, 12A: Inorganic material layer
14: Electrode
20: Laminated body
20A, 20B, 20C: Resin layer-equipped semiconductor chip
21: Semiconductor substrate (silicon substrate)
22: Inorganic material layer
23, 23A: Resin layer
24, 25, 26: Electrode
33, 33A: Protective layer
34: Groove (Opening)
35: Foreign matter
36: Bonding surface
42: Dicing tape
44: Frame
L: Laser light
P: Plasma

1. A method of producing a resin layer-equipped semiconductor chip, the method comprising:
a laminated body preparation step of preparing a laminated body that comprises a semiconductor substrate and a resin layer stacked on the semiconductor substrate;
an attachment step of attaching the laminated body to a dicing tape such that the resin layer is exposed;
a protective layer formation step of forming a protective layer on the resin layer of the laminated body;
a groove formation step of forming grooves penetrating through the protective layer and the resin layer by laser ablation;
a dicing step of singulating the semiconductor substrate through the grooves; and
a protective layer removal step of removing the protective layer after the dicing step.

2. The method of producing a resin layer-equipped semiconductor chip according to claim 1, wherein the laminated body comprises an electrode exposed from a part of the resin layer.

3. The method of producing a resin layer-equipped semiconductor chip according to claim 1, wherein the resin layer comprises, on its surface, at least one functional group selected from the group consisting of a silanol group, an amino group, an epoxy group, a hydroxy group, and an unsaturated bond-containing functional group.

4. The method of producing a resin layer-equipped semiconductor chip according to claim 1, wherein the resin layer comprises a siloxane bond and at least one bond selected from the group consisting of an ester bond, an ether bond, an amide bond, and an imide bond.

5. The method of producing a resin layer-equipped semiconductor chip according to claim 1, wherein the protective layer is a water-soluble resin layer formed of a water-soluble resin.

6. The method of producing a resin layer-equipped semiconductor chip according to claim 1, wherein, in the laminated body, an inorganic material layer is stacked on a side of the semiconductor substrate opposite to the side in which the resin layer is stacked.

7. The method of producing a resin layer-equipped semiconductor chip according to claim 1, wherein, in the dicing step, the protective layer and the resin layer on which the grooves are formed are used as a mask, and parts of the semiconductor substrate are plasma-etched through the grooves to singulate the semiconductor substrate.

8. A method of producing a substrate laminated body, the method comprising:
a stacking step of peeling off a resin layer-equipped semiconductor chip, which is produced by the method of producing a resin layer-equipped semiconductor chip according to claim 1, from the dicing tape, and stacking the resin layer-equipped semiconductor chip on other semiconductor substrate or other semiconductor chip such that the resin layer of the resin layer-equipped semiconductor chip is in contact with the other semiconductor substrate or the other semiconductor chip; and
a heating step of heating and thereby bonding the thus stacked resin layer-equipped semiconductor chip and the other semiconductor substrate or the other semiconductor chip.

9. The method of producing a substrate laminated body according to claim 8, wherein
the other semiconductor substrate or the other semiconductor chip comprises an inorganic material layer, and
in the stacking step, the stacking is performed such that the resin layer of the resin layer-equipped semiconductor chip is in contact with the inorganic material layer of the other semiconductor substrate or the other semiconductor chip.
